(19) United States
(12) Patent Application Publication
(10) Pub. No.: US 2024/0397752 A1
(43) Pub. Date: Nov. 28, 2024

(54) DISPLAY DEVICE AND METHOD FOR FABRICATION THEREOF

(71) Applicant: Samsung Display Co., LTD., Yongin-si (KR)

(72) Inventors: Hyun Eok SHIN, Yongin-si (KR); Joon Yong PARK, Yongin-si (KR); Dong Min LEE, Yongin-si (KR)

(21) Appl. No.: 18/584,832

(22) Filed: Feb. 22, 2024

(30) Foreign Application Priority Data
May 24, 2023 (KR) 10-2023-0066981

(51) Int. Cl. H10K 59/122; H10K 59/12; H10K 102/00

(52) U.S. Cl. CPC H10K 59/122; H10K 59/1201; H10K 2102/351

(57) ABSTRACT

A display device includes a first pixel electrode and a second pixel electrode spaced apart from each other on a substrate, a first bank layer disposed on the substrate and exposing the first pixel electrode and the second pixel electrode, a first light-emitting layer disposed on the first pixel electrode and a second light-emitting layer disposed on the second pixel electrode, a first common electrode disposed on the first light-emitting layer and a second common electrode disposed on the second light-emitting layer, a second bank layer disposed on the first bank layer and exposing the first common electrode and the second common electrode, and a third bank layer disposed on the second bank layer and including metal nitride, wherein the third bank layer includes a tip protruding further than the sidewall of the second bank layer.

This application claims priority to Korean Patent Application No. 10-2023-0066981, filed on May 24, 2023, and all the benefits accruing therefrom under 35 U.S.C. § 119, the content of which in its entirety is herein incorporated by reference.

### BACKGROUND

### 1. Field

The disclosure relates to a display device and a method for fabrication thereof.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device and an organic light-emitting display device. Among the flat panel display devices, in the light-emitting display device, since each of pixels of a display panel includes a light-emitting element capable of emitting light by itself, an image may be displayed without a backlight unit providing light to the display panel.

### SUMMARY

Features of the disclosure provide a display device capable of forming light-emitting elements separated for each emission area without a mask process.

Features of the disclosure also provide a display device in which light emission deviation that may occur in each pixel due to damage to a bank structure caused by an etching process performed during a manufacturing process of a display device is reduced.

Features of the disclosure also provide a method of fabricating a display device with reduced emission deviation that may occur in each pixel due to damage to a bank structure by an etching process performed during the manufacturing process of the display device.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a display device comprises a first pixel electrode and a second pixel electrode spaced apart from each other on a substrate, a first bank layer disposed on the substrate and exposing the first pixel electrode and the second pixel electrode, a first light-emitting layer disposed on the first pixel electrode and a second light-emitting layer disposed on the second pixel electrode, a first common electrode disposed on the first light-emitting layer and a second common electrode disposed on the second light-emitting layer, a second bank layer disposed on the first bank layer and exposing the first common electrode and the second common electrode, and a third bank layer disposed on the second bank layer and including metal nitride, wherein the third bank layer includes a tip protruding further than a sidewall of the second bank layer.

In an embodiment, the first bank layer may include insulating material, and the second bank layer may include metal material.

In an embodiment, a thickness of the third bank layer may be in a range of about 100 angstroms (Å) to about 1500 Å.

In an embodiment, the third bank layer may include a first metal nitride layer including the metal nitride and a first metal layer including a Group 5 metal element.

In an embodiment, the first metal nitride layer may contact the second bank layer, the first metal layer may be disposed on the first metal nitride layer, and the third bank layer further may include a second metal nitride layer disposed on the first metal layer and include the metal nitride.

In an embodiment, a thickness of the first metal nitride layer may be in a range of about 50 angstroms (Å) to about 300 Å, and a thickness of the first metal layer may be in a range of about 100 Å to about 1000 Å.

In an embodiment, the metal nitride may be titanium nitride (TiN).

In an embodiment, the second bank layer may include one or more aluminum (Al) and titanium (Ti).

In an embodiment, a width of the tip of the third bank layer may be in a range of about 0.1 micrometer (μm) to about 1.0 μm.

In an embodiment, the tip of the third bank layer may overlap the first common electrode in a thickness direction of the substrate.

In an embodiment, each of the first common electrode and the second common electrode may be in direct contact with the sidewall of the second bank layer.

In an embodiment, a maximum distance from the substrate to the first common electrode may be smaller than a maximum distance from the substrate to the second bank layer.

In an embodiment, the display device may further comprise a first organic pattern disposed on the third bank layer and including a same material as that of the first light-emitting layer, a first electrode pattern disposed on the first organic pattern and including a same material as that of the first common electrode, a second organic pattern disposed on the third bank layer and including a same material as that of the second light-emitting layer, and a second electrode pattern disposed on the second organic pattern and including a same material as that of the second common electrode.

In an embodiment, the display device may further comprise a first inorganic layer disposed on the sidewall of the second bank layer adjacent to the first common electrode and disposed on the first common electrode and the first electrode pattern, and a second inorganic layer disposed on the sidewall of the second bank layer adjacent to the second common electrode and disposed on the second common electrode and the second electrode pattern, wherein the first inorganic layer and the second inorganic layer may be spaced apart, and a portion of the third bank layer may be exposed in a space between the first inorganic layer and the second inorganic layer.

In an embodiment, the display device may further comprise a third pixel electrode disposed to be spaced apart from the second pixel electrode on the substrate, a third light-emitting layer disposed on the third pixel electrode, and a third common electrode disposed on the third light-emitting layer and disposed to be spaced apart from the second common electrode, wherein the first bank layer exposes the third pixel electrode.

In an embodiment, the display device may further comprise a third organic pattern disposed on the third bank layer and including a same material as that of the third light-emitting layer, a third electrode pattern disposed on the third organic pattern and including a same material as that of the third common electrode, and a third inorganic layer disposed on the sidewall of the second bank layer adjacent to the third common electrode and disposed on the third common electrode and the third electrode pattern.

In an embodiment of the disclosure, a method for fabricating a display device comprises forming a plurality of pixel electrodes spaced apart from each other on a substrate, forming a first bank material layer on the substrate and the plurality of pixel electrodes, forming a second bank material layer on the first bank material layer; and forming a third bank material layer including a metal nitride on the second bank material layer; defining a first hole overlapping a first pixel electrode among the plurality of pixel electrodes and penetrating the first bank material layer, the second bank material layer and the third bank material layer to expose the first pixel electrode; wet etching a sidewall of the second bank material layer exposed through the first hole to form a tip of the third bank material layer protruding further than the sidewall of the second bank material layer; forming a first light-emitting layer and a first common electrode on the first pixel electrode, and forming a first inorganic material layer on the first common electrode and the third bank material layer; and removing a portion of the first inorganic material layer disposed on the third bank material layer.

In an embodiment, the metal nitride may be titanium nitride (TiN), and the second bank material layer may include one or more aluminum (Al) and titanium (Ti).

In an embodiment, the first inorganic material layer may include any one of silicon oxide, silicon nitride, and silicon oxynitride, in removing the portion of the first inorganic material layer, a mask pattern may be formed on the first inorganic material layer disposed in the first hole, and fluorine (F)-based etchant may be used to etch the first inorganic material layer not covered by the mask pattern in a dry etching process.

In an embodiment, in the forming the first light-emitting layer and the first common electrode on the first pixel electrode and the forming the first inorganic material layer on the first common electrode and the third bank material layer, a first organic pattern material layer disposed on the third bank material layer and including a same material as that of the first light-emitting layer may be formed and a first electrode pattern material layer disposed on the first organic pattern material layer and including a same material as that of the first common electrode may be formed, and, in the removing the portion of the first inorganic material layer, the first electrode pattern material layer and the first organic pattern material layer not covered by the mask pattern may be etched simultaneously with the first inorganic material layer through a dry etching using the fluorine (F)-based etchant.

In a display device and a method of fabricating the same in an embodiment, a third bank layer disposed on top of the bank structure may have stable mechanical strength to have a structure that may prevent damage during a manufacturing process of the display device. Accordingly, in the display device, bending of the protruding tip of the bank structure may be prevented, and a luminance difference between the light-emitting elements may be reduced by securing a sufficient contact area between the common electrode and the bank structure.

In a display device in an embodiment, since the third bank layer has a thin thickness, the overall thickness of the display device may be reduced, and fine patterning in a subsequent process may be performed smoothly.

It should be noted that effects of the disclosure are not limited to those described above and other effects of the disclosure will be apparent to those skilled in the art from the following descriptions.

### BRIEF DESCRIPTION OF THE DRAWINGS

The above and other features and features of the disclosure will become more apparent by describing in detail embodiments thereof with reference to the attached drawings, in which:

FIG. 1 is a perspective view of an embodiment of an electronic device;

FIG. 2 is a perspective view showing an embodiment of a display device included in an electron device;

FIG. 3 is a cross-sectional view of the display device of FIG. 2 seen from the side;

FIG. 4 is a plan view showing an embodiment of a display layer of a display device;

FIG. 5 is a cross-sectional view illustrating an embodiment of a portion of a display device;

FIG. 6 is an enlarged view of area μl of FIG. 5;

FIG. 7 is a cross-sectional view showing a tip failing to maintain its shape and being in a bent state;

FIGS. 8 to 15 are cross-sectional views sequentially illustrating an embodiment of a fabricating process of a display device;

FIG. 16 is a cross-sectional view illustrating an embodiment of a part of a display device;

FIG. 17 is a cross-sectional view illustrating an embodiment of a part of a display device; and

FIG. 18 is a cross-sectional view illustrating an embodiment of a part of a display device.

### DETAILED DESCRIPTION

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Hereinafter, embodiments will be described with reference to the accompanying drawings.

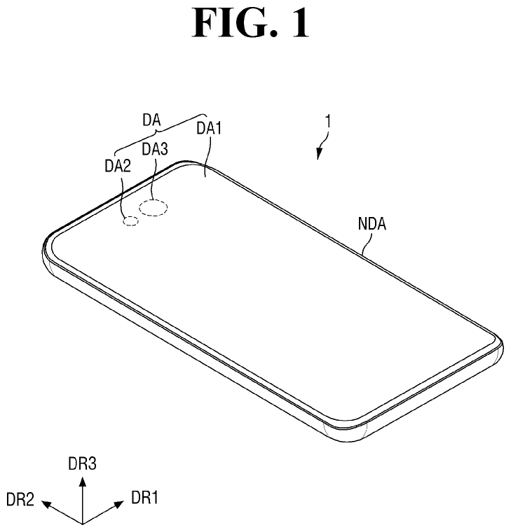

FIG. 1 is a perspective view of an embodiment of an electronic device.

Referring to FIG. 1, an electronic device 1 displays a moving image or a still image. The electronic device 1 may refer to any electronic device that provides a display screen. In an embodiment, the electronic device 1 may include a television set, a laptop computer, a monitor, an electronic billboard, the Internet of Things devices, a mobile phone, a smart phone, a tablet personal computer (“PC”), an electronic watch, a smart watch, a watch phone, a head-mounted display device, a mobile communications terminal, an electronic notebook, an electronic book, a portable multimedia player (“PMP”), a navigation device, a game console and a digital camera, a camcorder, etc., for example.

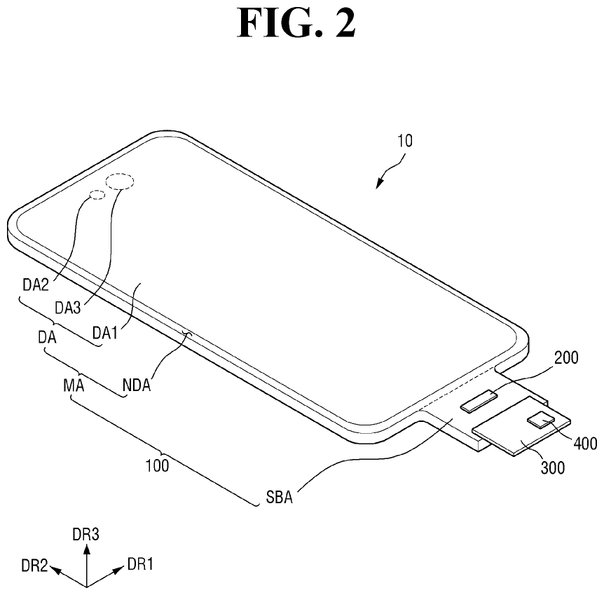

The electronic device 1 may include a display device 10 (refer to FIG. 2) for providing a display screen. In embodiments, the display device may include an inorganic light-emitting diode display device, an organic light-emitting display device, a quantum-dot light-emitting display device, a plasma display device, a field emission display device, etc. In the following description, an organic light-emitting diode display device is employed in an embodiment of the display device 10, but the disclosure is not limited thereto. Any other display device may be employed as long as the technical idea of the disclosure may be equally applied.

The shape of the electronic device 1 may be modified in a variety of ways. In an embodiment, the electronic device 1 may have shapes such as a rectangle with longer lateral sides, a rectangle with longer vertical sides, a square, a quadrangle with rounded corners (vertices), other polygons, a circle, etc., for example. The shape of a display area DA of the electronic device 1 may also be similar to the overall shape of the electronic device 1. In the example shown in FIG. 1, the electronic device 1 has a rectangular shape with the longer sides in a second direction DR2.

The electronic device 1 may include the display area DA and a non-display area NDA. In the display area DA, images are displayed. In the non-display area NDA, images are not displayed. The display area DA may be also referred to as an active area, while the non-display area NDA may also be also referred to as an inactive area. The display area DA may generally occupy the center of the electronic device 1.

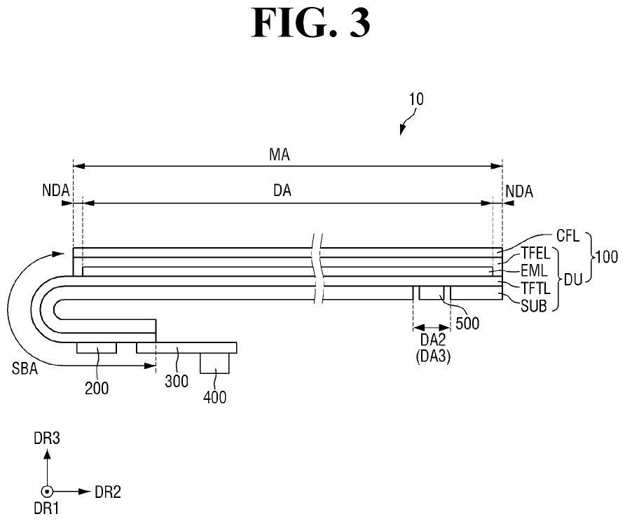

The display area DA may include a first display area DA1, a second display area DA2 and a third display area DA3. In the second display area DA2 and the third display area DA3, components for adding a variety of features to the electronic device 1 may be disposed. In other words, the second display area DA2 and the third display area DA3 may be also referred to as component areas. The components may be an optical device 500 shown in FIG. 3.

FIG. 2 is a perspective view showing an embodiment of a display device included in an electron device.

Referring to FIG. 2, the electronic device 1 in the embodiment of the disclosure may include a display device 10. The display device 10 may provide a display screen where images are displayed in the electronic device 1. The display device 10 may have a shape similar to that of the electronic device 1 when viewed from the top. In an embodiment, the display device 10 may have a shape similar to a rectangle having shorter sides in a first direction DR1 and longer sides in the second direction DR2, for example. The corners where the shorter sides in the first direction DR1 meet the longer sides in the second direction DR2 may be rounded with a curvature. It should be understood, however, that the disclosure is not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include the display area DA including pixels for displaying images, and the non-display area NDA disposed around the display area DA. The display area DA may include the first display area DA1, the second display area DA2 and the third display area DA3. The display area DA may output lights from a plurality of emission areas or a plurality of open areas. In an embodiment, the display panel 100 may include a pixel circuit including switching elements, a pixel-defining layer that defines the emission areas or the opening areas, and a self-light-emitting element, for example.

In an embodiment, the self-light-emitting element may include, but is not limited to, at least one of: an organic light-emitting diode including an organic emissive layer, a quantum-dot light-emitting diode (“quantum LED”) including a quantum-dot emissive layer, an inorganic light-emitting diode (“inorganic LED”) including an inorganic semiconductor, and a micro light-emitting diode (micro LED), for example.

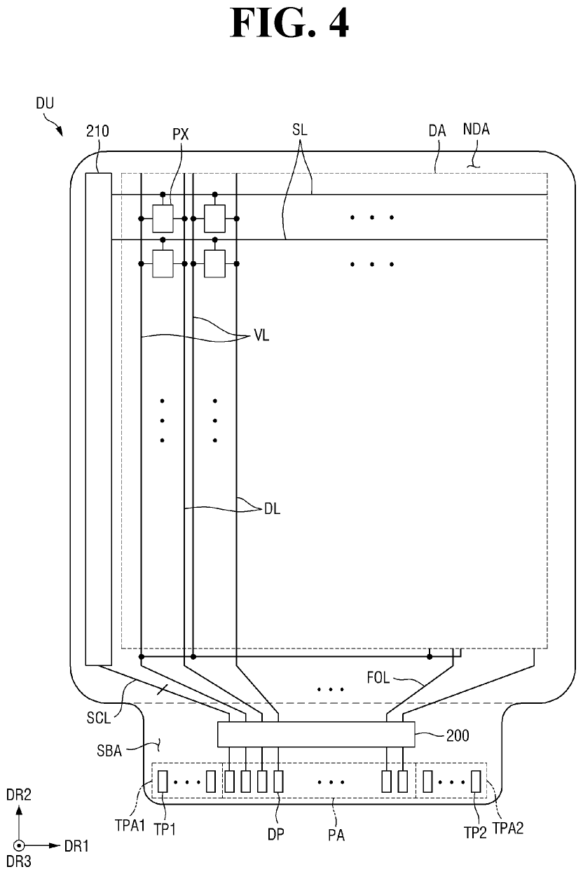

The non-display area NDA may be disposed on the outer side of the display area DA. The non-display area NDA may be defined as the edge area of the main area MA of the display panel 100. The non-display area NDA may include a scan driver 210 (or injection driver) (refer to FIG. 4) providing scan signals (or injection signals) to scan lines (or injection lines), and fan-out lines FOL (refer to FIG. 4) connecting a display driver 200 to the display area DA.

The subsidiary area SBA may be extended from one side of the main area MA. The subsidiary area SBA may include a flexible material that may be bent, folded, or rolled. In an embodiment, when the subsidiary area SBA is bent, the subsidiary area SBA may overlap the main area MA in the thickness direction (third direction DR3), for example. The subsidiary area SBA may include pads connected to the display driver 200 and the circuit board 300. In another embodiment, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line, and may supply a scan control signal to the scan driver. The display driver 200 may be implemented as an integrated circuit (“IC”) and may be attached on the display panel 100 by a chip-on-glass (“COG”) technique, a chip-on-plastic (“COP”) technique, or ultrasonic bonding. In an embodiment, the display driver 200 may be disposed in the subsidiary area SBA and may overlap with the main area MA in the thickness direction (third direction DR3) as the subsidiary area SBA is bent, for example. In another embodiment, the display driver 200 may be disposed (e.g., mounted) on the circuit board 300.

The circuit board 300 may be attached on the pad area of the display panel 100 using an anisotropic conductive film (“ACF”). Lead lines of the circuit board 300 may be electrically connected to the pads of the display panel 100. The circuit board 300 may be a flexible printed circuit board (“FPCB”), a printed circuit board (“PCB”), or a flexible film such as a chip-on-film (“COF”).

The touch driver 400 may be disposed (e.g., mounted) on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. In an embodiment, the touch driving signal may be a pulse signal having a predetermined frequency, for example. The touch driver 400 may determine whether a touch is input and may find the coordinates of the touch based on the amount of the change in the capacitance between the touch electrodes. The touch driver 400 may be implemented as an IC.

FIG. 3 is a cross-sectional view of the display device of FIG. 2 seen from the side.

Referring to FIG. 3, the display panel 100 may include a display layer DU and a color filter layer CFL. The display layer DU may include a substrate SUB, a thin-film transistor layer TFTL, a light-emitting element layer EML and a thin-film encapsulation layer TFEL.

The substrate SUB may be a base substrate or a base member. The substrate SUB may be a flexible substrate that may be bent, folded, or rolled. In an embodiment, the substrate SUB may include, but is not limited to, a polymer resin such as polyimide PI, for example. In another embodiment, the substrate SUB may include a glass material or a metal material.

The thin-film transistor layer TFTL may be disposed on the substrate SUB. The thin-film transistor layer TFTL may include a plurality of thin-film transistors forming pixel circuits of pixels. The thin-film transistor layer TFTL may further include scan lines, data lines, voltage lines, scan control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. In an embodiment, when the scan driver is formed on one side of the non-display area NDA of the display panel 100, the scan driver may include thin-film transistors, for example.

The thin-film transistor layer TFTL may be disposed in the display area DA, the non-display area NDA and the subsidiary area SBA. The thin-film transistors in the pixels, the scan lines, the data lines, and the power supply lines on the thin-film transistor layer TFTL may be disposed in the display area DA. The scan control lines and the fan-out lines in the thin-film transistor layer TFTL may be disposed in the non-display area NDA. The lead lines of the thin-film transistor layer TFTL may be disposed in the subsidiary area SBA.

The light-emitting element layer EML may be disposed on the thin-film transistor layer TFTL. The light-emitting element layer EML may include a plurality of light-emitting elements each including a first electrode, a second electrode and a light-emitting layer to emit light, and a pixel-defining layer for defining the pixels. The plurality of light-emitting elements in the light-emitting element layer EML may be disposed in the display area DA.

In an embodiment, the light-emitting layer may be an organic light-emitting layer including or consisting of an organic material. The light-emitting layer may include a hole transporting layer, an organic light-emitting layer and an electron transporting layer. When the first electrode receives a voltage and the second electrode receives a cathode voltage through the thin-film transistors on the thin-film transistor layer TFTL, the holes and electrons may move to the organic light-emitting layer through the hole transporting layer and the electron transporting layer, respectively, such that they combine in the organic light-emitting layer to emit light.

In another embodiment, the light-emitting elements may include quantum-dot light-emitting diodes each including a quantum-dot light-emitting layer, inorganic light-emitting diodes each including an inorganic semiconductor, or micro light-emitting diodes.

The thin-film encapsulation layer TFEL may cover the upper and side surfaces of the light-emitting element layer EML, and may protect the light-emitting element layer EML. The thin-film encapsulation layer TFEL may include at least one inorganic layer and at least one organic layer for encapsulating the light-emitting element layer EML.

A touch sensing layer (not shown) may be disposed on the display layer DU. The touch sensing layer may obtain the coordinates of the touch input point by capacitive sensing. The capacitive sensing may obtain coordinate information of a touched point by self-capacitance manner or mutual-capacitance manner. It should be understood, however, that the disclosure is not limited thereto.

The color filter layer CFL may be disposed on the thin-film encapsulation layer TFEL. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL may prevent distortion of colors due to the reflection of external light.

Since the color filter layer CFL is disposed directly on the thin-film encapsulation layer TFEL, the display device 10 may desire no separate substrate for the color filter layer CFL. Therefore, the thickness of the display device 10 may be relatively small.

In some embodiments, the display device 10 may further include an optical device 500. The optical device 500 may be disposed in the second display area DA2 or the third display area DA3. The optical device 500 may output or receive light in infrared, ultraviolet, and visible ranges. In an embodiment, the optical device 500 may be an optical sensor that senses light incident on the display device 10, such as a proximity sensor, an illuminance sensor, a camera sensor, a finger sensor and an image sensor, for example.

FIG. 4 is a plan view showing an embodiment of a display layer of a display device.

Referring to FIG. 4, the display layer DU may include a display area DA and a non-display area NDA.

The display area DA may be disposed at the center of display panel 100. In the display area DA, a plurality of pixels PX, a plurality of scan lines SL, a plurality of data lines DL and a plurality of voltage lines VL may be disposed. Each of the plurality of pixels PX may be defined as the minimum unit that outputs light.

The plurality of scan lines SL may provide the scan signals received from the scan driver 210 to the plurality of pixels PX. The plurality of scan lines SL may be extended in the first direction DR1 and may be spaced apart from one another in the second direction DR2 intersecting the first direction DR1.

The plurality of data lines DL may provide the data voltages received from the display driver 200 to the plurality of pixels PX. The plurality of data lines DL may be extended in the second direction DR2 and may be spaced apart from one another in the first direction DR1.

The plurality of voltage lines VL may provide the supply voltage received from the display driver 200 to the plurality of pixels PX. The supply voltage may be at least one of a driving voltage, an initialization voltage, a reference voltage and a low-potential voltage. The plurality of voltage lines VL may be extended in the second direction DR2 and may be spaced apart from one another in the first direction DR1.

The non-display area NDA may surround the display area DA. In the non-display area NDA, the scan driver 210, fan-out lines FOL, and scan control lines SCL may be disposed. The scan driver 210 may generate a plurality of scan signals based on a scan control signal, and may sequentially supply the scan signals to the scan lines SL in a sequential order.

The fan-out lines FOL may be extended from the display driver 200 to the display area DA. The fan-out lines FOL may supply the data voltage received from the display driver 200 to the plurality of data lines DL.

A scan control line SCL may be extended from the display driver 200 to the scan driver 210. The scan control line SCL may provide the scan control signal received from the display driver 200 to the scan driver 210.

The subsidiary area SBA may include the display driver 200, a pad area PA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the luminance of the plurality of pixels PX may be controlled. The display driver 200 may supply a scan control signal to the scan driver 210 through the scan control line SCL.

The pad area PA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a material such as an anisotropic conductive film and a self assembly anisotropic conductive paste (“SAP”). In an embodiment, the first touch pad area TPA1 may include first pads TP1 and the second touch pad area TPA2 may include second pads TP2.

The pad area PA may include a plurality of display pads DP. The plurality of display pads DP may be connected to a graphic system through the circuit board 300. The plurality of display pads DP may be connected to the circuit board 300 to receive digital video data and may supply the digital video data to the display driver 200.

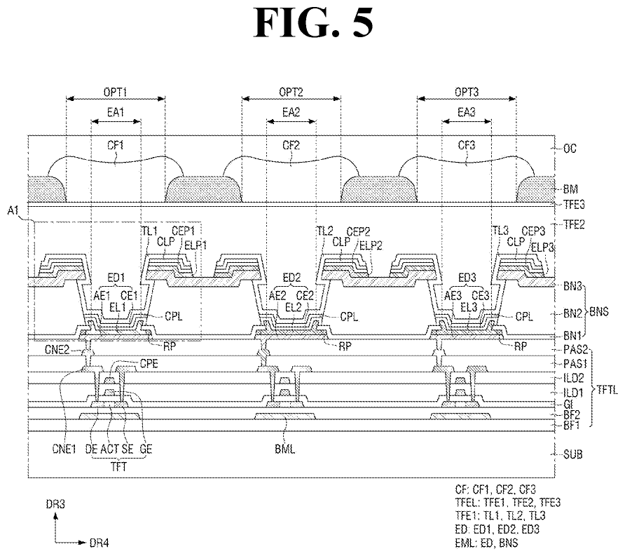

FIG. 5 is a cross-sectional view illustrating an embodiment of a portion of a display device. FIG. 5 is a partial cross-sectional view of the display device 10, showing cross-sections of a substrate SUB, a thin-film transistor layer TFTL, a light-emitting element layer EML, a thin-film encapsulation layer TFEL, and a color filter layer CFL of the display layer DU.

Referring to FIG. 5, a display panel 100 of the display device 10 may include a display layer DU and a color filter layer CFL. The display layer DU may include a substrate SUB, a thin-film transistor layer TFTL, a light-emitting element layer EML and a thin-film encapsulation layer TFEL. The display panel 100 includes a light shielding layer BM disposed on the thin-film encapsulation layer TFEL and the color filters CF1, CF2 and CF3 of the color filter layer CFL may be disposed on the light shielding layer BM.

The substrate SUB may be a base substrate or a base member. The substrate SUB may be a flexible substrate that may be bent, folded, and rolled. In an embodiment, the substrate SUB may include a polymer resin such as polyimide (“PI”), for example, but is not limited thereto. In another embodiment, the substrate SUB may include a glass material or a metal material.

The thin-film transistor layer TFTL may include a first buffer layer BF1, a lower metal layer BML, a second buffer layer BF2, a thin-film transistor TFT, a gate insulating layer GI, a first inter-dielectric layer ILD1, a capacitor electrode CPE, a second inter-dielectric layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic layer capable of preventing the air or moisture from being permeated thereinto. In an embodiment, the first buffer layer BF1 may include a plurality of inorganic layers that are alternately stacked, for example.

The lower metal layer BML may be disposed on the first buffer layer BF1. In an embodiment, the lower metal layer BML may include or consist of a single layer or multiple layers including one of molybdenum (Mo), aluminum (Al), chromium (Cr), gold (Au), titanium (Ti), nickel (Ni), neodymium (Nd) and copper (Cu), or their alloy, for example.

The second buffer layer BF2 may cover the first buffer layer BF1 and the lower metal layer BML. The second buffer layer BF2 may include an inorganic layer capable of preventing permeation of the air or moisture from occurring. In an embodiment, the second buffer layer BF2 may include a plurality of inorganic layers that are alternately stacked, for example.

The thin-film transistor TFT may be disposed on the second buffer layer BF2, and may constitute a pixel circuit of each of a plurality of pixels. In an embodiment, the thin-film transistor TFT may be a driving transistor or a switching transistor of the pixel circuit, for example. The thin-film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction DR3, and may be insulated from the gate electrode GE by the gate insulating layer GI. A portion of the semiconductor layer ACT may form the source electrode SE and the drain electrode DE through condutorization of a material of the semiconductor layer ACT.

The gate electrode GE may be disposed on the gate insulating layer GI. The gate electrode GE may overlap the semiconductor layer ACT with the gate insulating layer GI interposed therebetween in the thickness direction DR3.

The gate insulating layer GI may be disposed on the semiconductor layer ACT. In an embodiment, the gate insulating layer GI may cover the semiconductor layer ACT and the second buffer layer BF2, and may insulate the semiconductor layer ACT from the gate electrode GE, for example. The gate insulating layer GI may include a contact hole through which the first connection electrode CNE1 passes.

The first inter-dielectric layer ILD1 may cover the gate electrode GE and the gate insulating layer GI. The first inter-dielectric layer ILD1 may define a contact hole through which the first connection electrode CNE1 passes. The contact hole of the first inter-dielectric layer ILD1 may be connected to a contact hole of the gate insulating layer GI and a contact hole of the second inter-dielectric layer ILD2.

The capacitor electrode CPE may be disposed on the first inter-dielectric layer ILD1. The capacitor electrode CPE may overlap the gate electrode GE in the thickness direction DR3. The capacitor electrode CPE and the gate electrode GE may form capacitance.

The second inter-dielectric layer ILD2 may cover the capacitor electrode CPE and the first inter-dielectric layer ILD1. The second inter-dielectric layer ILD2 may define a contact hole through which the first connection electrode CNE1 passes. The contact hole of the second inter-dielectric layer ILD2 may be extended to the contact hole of the first inter-dielectric layer ILD1 and the contact hole of the gate insulating layer GI.

The first connection electrode CNE1 may be disposed on the second inter-dielectric layer ILD2. The first connection electrode CNE1 may electrically connect the drain electrode DE of the thin-film transistor TFT with the second connection electrode CNE2. The first connection electrode CNE1 may be inserted into the contact holes provided in the second inter-dielectric layer ILD2, the first inter-dielectric layer ILD1 and the gate insulating layer GI, and then may contact the drain electrode DE of the thin-film transistor TFT.

The first passivation layer PAS1 may cover the first connection electrode CNE1 and the second inter-dielectric layer ILD2. The first passivation layer PAS1 may protect the thin-film transistor TFT. The first passivation layer PAS1 may define a contact hole through which the second connection electrode CNE2 passes.

The second connection electrode CNE2 may be disposed on the first passivation layer PAS1. The second connection electrode CNE2 may electrically connect the first connection electrode CNE1 with pixel electrodes AE1, AE2 and AE3 of the light-emitting element ED. The second connection electrode CNE2 may be inserted into the contact hole provided in the first passivation layer PAS1, and then may contact the first connection electrode CNE1.

The second passivation layer PAS2 may cover the second connection electrode CNE2 and the first passivation layer PAS1. The second passivation layer PAS2 may define a contact hole through which the pixel electrodes AE1, AE2 and AE3 of the light-emitting element ED pass.

The light-emitting element layer EML may be disposed on the thin-film transistor layer TFTL. The light-emitting element layer EML may include a light-emitting element ED and a plurality of bank structures BNS. The light-emitting element ED may include pixel electrodes AE1, AE2 and AE3, light-emitting layers EL1, EL2 and EL3, and common electrodes CE1, CE2 and CE3.

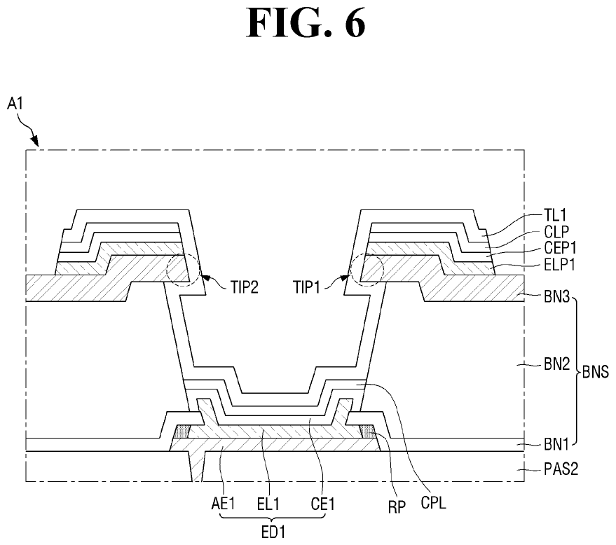

FIG. 6 is an enlarged view illustrating a first emission area, specifically an area μl of FIG. 5.

Referring to FIG. 6 in addition to FIG. 5, the display device 10 may include a plurality of emission areas EA1, EA2 and EA3 disposed in the display area DA. The emission areas EA1, EA2 and EA3 may include a first emission area EA1, a second emission area EA2 and a third emission area EA3, which emit light of different colors. Each of the first to third emission areas EA1, EA2 and EA3 may emit red light, green light or blue light, and a color of light emitted from each of the emission areas EA1, EA2 and EA3 may vary depending on a type of the light-emitting element ED disposed in the light-emitting element layer EML. In an embodiment, the first pixel electrode AE1, the first light-emitting layer EL1, and the first common electrode CE1 may be sequentially stacked so that the first emission area EA1 may emit first light of a red color, the second pixel electrode AE2, the second light-emitting layer EL2, and the second common electrode CE2 may be sequentially stacked so that the second emission area EA2 may emit second light of a green color, and the third pixel electrode AE3, the third light-emitting layer EL3, and the third common electrode CE3 may be sequentially stacked so that the third emission area EA3 may emit third light of a blue color, but the disclosure is not limited thereto.

A plurality of openings defined in the bank structure BNS of the light-emitting element layer EML are defined along a boundary of the bank structure BNS. The openings may include the first to third emission areas EA1, EA2 and EA3. The first opening may include not only the first emission area EA1 but also an exposed area of the first pixel electrode AE1 that is not covered by a first bank layer BN1 and a residual pattern RP.

In an embodiment, areas or sizes of the first to third emission areas EA1, EA2 and EA3 may be the same as one another. In an embodiment, in the display device 10, the first emission area EA1, the second emission area EA2 and the third emission area EA3 may have the same area, for example, but the disclosure is not limited thereto. In the display device 10, the areas or sizes of the first to third emission areas EA1, EA2 and EA3 may be different from one another. In an embodiment, the area of the second emission area EA2 may be greater than that of each of the first emission area EA1 and the third emission area EA3, and the area of the third emission area EA3 may be greater than that of the first emission area EA1, for example. The intensity of light emitted from the corresponding emission areas EA1, EA2 and EA3 may vary depending on the area of each of the emission areas EA1, EA2 and EA3, and the area of each of the emission areas EA1, EA2 and EA3 may be adjusted to control a color of a screen displayed on the display device 10 or the electronic device 1. In the embodiment of FIG. 5, the areas of the emission areas EA1, EA2 and EA3 are the same as one another, but are not limited thereto. Areas of the emission areas EA1, EA2 and EA3 may be freely adjusted according to the color of the screen desired by the display device 10 and the electronic device 1. In addition, the areas of the emission areas EA1, EA2 and EA3 are related to light efficiency and lifespan of the light-emitting element ED and may have a trade-off relationship with reflection by external light. Areas of the emission areas EA1, EA2 and EA3 may be adjusted in consideration of the above matters.

In the display device 10, one first emission area EA1, one second emission area EA2 and one third emission area EA3, which are adjacent to one another, may form one pixel group. One pixel group may include emission areas EA1, EA2 and EA3 that emit light of different colors to express a white gray scale, but is not limited thereto. Various modifications may be made in combination of the emission areas EA1, EA2 and EA3 constituting one pixel group depending on the arrangement of the emission areas EA1, EA2 and EA3 and a color of light emitted from each of the emission areas EA1, EA2 and EA3.

The display device 10 may include a plurality of light-emitting elements ED1, ED2 and ED3 disposed in their respective emission areas EA1, EA2 and EA3 different from one another. The light-emitting elements ED1, ED2 and ED3 may include a first light-emitting element ED1 disposed in the first emission area EA1, a second light-emitting element ED2 disposed in the second emission area EA2 and a third light-emitting element ED3 disposed in the third emission area EA3. The light-emitting elements ED1, ED2 and ED3 include pixel electrodes AE1, AE2 and AE3, light-emitting layers EL1, EL2 and EL3 and common electrodes CE1, CE2 and CE3. The light-emitting elements ED1, ED2 and ED3 disposed in different emission areas EA1, EA2 and EA3 may emit light of different colors depending on materials of the light-emitting layers EL1, EL2 and EL3. In an embodiment, the first light-emitting element ED1 disposed in the first emission area EA1 may emit red light of a first color, the second light-emitting element ED2 disposed in the second emission area EA2 may emit green light of a second color, and the third light-emitting element ED3 disposed in the third emission area EA3 may emit blue light of a third color, for example. The first to third emission areas EA1, EA2 and EA3 constituting one pixel may include light-emitting elements ED1, ED2 and ED3 emitting light of different colors, thereby expressing a white gray scale.

The pixel electrodes AE1, AE2 and AE3 may be disposed on the second passivation layer PAS2. The pixel electrodes AE1, AE2 and AE3 may be disposed to overlap the emission area or one of the openings of the bank structure BNS. The pixel electrodes AE1, AE2 and AE3 may be electrically connected to the drain electrodes DE of the thin-film transistors TFT through the first and second connection electrodes CNE1 and CNE2.

The pixel electrodes AE1, AE2 and AE3 may be respectively disposed in the plurality of emission areas EA1, EA2 and EA3. The pixel electrodes AE1, AE2 and AE3 may include a first pixel electrode AE1 disposed in the first emission area EA1, a second pixel electrode AE2 disposed in the second emission area EA2 and a third pixel electrode AE3 disposed in the third emission area EA3. The first pixel electrode AE1, the second pixel electrode AE2 and the third pixel electrode AE3 may be spaced apart from one another on the second passivation layer PAS2. In FIG. 5, the first to third pixel electrodes AE1, AE2 and AE3 are illustrated to be spaced apart in a fourth direction DR4. The fourth direction DR4 is any one direction in a plan view including the first direction DR1 and second direction DR2. The pixel electrodes AE1, AE2 and AE3 may be respectively disposed in different emission areas EA1, EA2 and EA3 to constitute the light-emitting elements ED1, ED2 and ED3 emitting light of different colors.

The display device 10 may include a plurality of bank structures BNS disposed on the thin-film transistor layer TFTL or the substrate SUB and defining a plurality of openings. The bank structure BNS may have a structure in which bank layers BN1, BN2 and BN3 including different materials are sequentially stacked, and may include a plurality of openings including emission areas EA1, EA2 and EA3. The light-emitting elements ED1, ED2 and ED3 of the display device 10 may be disposed to overlap the openings of the bank structure BNS.

The bank structure BNS may include a first bank layer BN1 disposed on the second passivation layer PAS2, a second bank layer BN2 disposed on the first bank layer BN1 and a third bank layer BN3 disposed on the second bank layer BN2.

The first bank layer BN1 may be disposed on the second passivation layer PAS2 and the pixel electrodes AE1, AE2 and AE3. The first bank layer BN1 may be disposed on the entirety of the surface of the second passivation layer PAS2 but partially overlap the pixel electrodes AE1, AE2 and AE3 while partially exposing upper surfaces of the pixel electrodes AE1, AE2 and AE3. The first bank layer BN1 may expose the pixel electrodes AE1, AE2 and AE3 through an opening or a portion overlapping the emission areas EA1, EA2 and EA3. A portion of the light-emitting layers EL1, EL2 and EL3 and a residual pattern RP to be described later may be disposed between the first bank layer BN1 and the pixel electrodes AE1, AE2 and AE3. The first bank layer BN1 may include an inorganic insulating material. In an embodiment, the first bank layer BN1 may include one or more of aluminum oxide, titanium oxide, tantalum oxide, hafnium oxide, zinc oxide, silicon oxide, silicon nitride, and silicon oxynitride, for example.

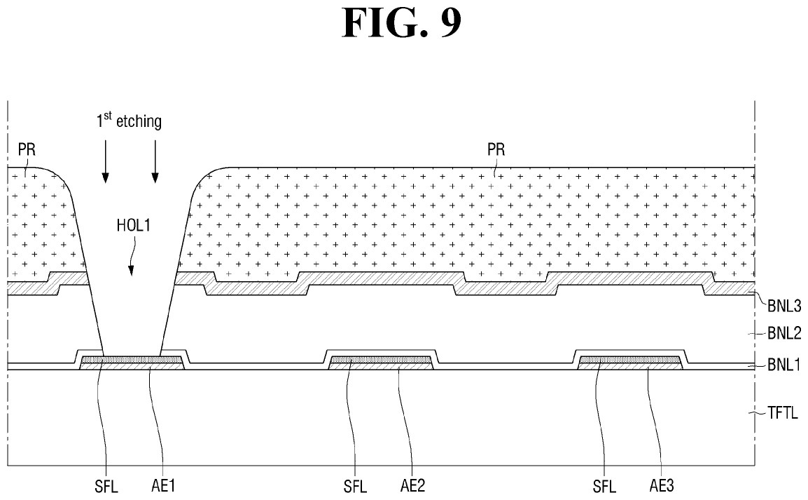

In an embodiment, the first bank layer BN1 may be disposed on the pixel electrodes AE1, AE2 and AE3, but may be spaced apart from upper surfaces of the pixel electrodes AE1, AE2 and AE3. The first bank layer BN1 may partially overlap but not directly contact the pixel electrodes AE1, AE2 and AE3, and portions of the light-emitting layers EL1, EL2 and EL3 of the respective light-emitting elements ED1, ED2 and ED3 may be disposed between the first bank layer BN1 and the respective pixel electrodes AE1, AE2 and AE3. In the manufacturing process of the display device 10, a sacrificial layer SFL (refer to FIG. 9) may be disposed on the pixel electrodes AE1, AE2 and AE3 before forming the first bank layer BN1. The first bank layer BN1 may be disposed to cover a portion of the sacrificial layer, and then may be spaced apart from the upper surfaces of the pixel electrodes AE1, AE2 and AE3 as the sacrificial layer is removed. In the subsequent deposition process of the light-emitting layers EL1, EL2 and EL3, a portion of the first bank layer BN1 may be disposed on the light-emitting layers EL1, EL2 and EL3 while filling the gap between the first bank layer BN1 and the pixel electrodes AE1, AE2 and AE3. However, the first bank layer BN1 may be in direct contact with the side surface of the pixel electrodes AE1, AE2 and AE3.

In an embodiment, the second bank layer BN2 may be disposed on the first bank layer BN1. A sidewall of the second bank layer BN2 may be disposed more inward than the sidewalls of the first bank layer BN1 and the third bank layer BN3. That is, the sidewall of the first bank layer BN1 may protrude toward the opening or the emission areas EA1, EA2 and EA3 compared to the sidewall of the second bank layer BN2. The sidewall of the third bank layer BN3 may protrude toward the opening or the emission areas EA1, EA2 and EA3 compared to the sidewall of the second bank layer BN2.

The third bank layer BN3 may include a tip TIP protruding from the second bank layer BN2 toward the opening or emission areas EA1, EA2 and EA3. Hereinafter, the tip TIP disposed at one edge of the third bank layer BN3 in respect to a fourth direction DR4 will be defined as a first tip TIP1, and the tip TIP disposed at the other edge in respect to the fourth direction DR4 will be defined as a second tip TIP2. Based on the fourth direction DR4, the other edge of the third bank layer BN3 may be the opposite side of the one edge of the third bank layer BN3.

The first tip TIP1 of the third bank layer BN3 may face the second tip TIP2 of the third bank layer BN3. Between the first tip TIP1 and the second tip TIP2 of the third bank layer BN3, an area in which the third bank layer BN3 is exposed may exist, not covered by the organic patterns ELP1 and ELP2 and the electrode patterns CEP1 and CEP2, which will be described later.

As the third bank layer BN3 protrudes toward the opening or the emission areas EA1, EA2 and EA3 further than the second bank layer BN2, an undercut may be formed below the tip TIP of the third bank layer BN3.

Shapes of the sidewalls of the second and third bank layers BN2 and BN3 may be structures formed due to a difference in etch rate in an etching process because the second bank layer BN2 and the third bank layer BN3 include the different materials from each other. In an embodiment, the third bank layer BN3 may include a material having an etch rate slower than that of the second bank layer BN2, and the second bank layer BN2 may be further etched in the etching process, such that undercuts may be formed under the tips TIP of the third bank layer BN3. In an embodiment, the second bank layer BN2 may include a metal material having relatively high electrical conductivity, and the third bank layer BN3 may include a metal nitride material.

In an embodiment, the second bank layer BN2 may include a metal material. The metal material of the second bank layer BN2 may be removed along with the third bank layer BN3 by dry etching, but any material that shows an etching rate different from that of the third bank layer BN3 with respect to a fluorine-based etchant and may form an undercut structure may be used. The second bank layer BN2 may include one or more of aluminum (Al) and titanium (Ti). Titanium (Ti) may easily control the distribution of the undercut structure and may lower the contact resistance.

The bank structure BNS may include openings forming the emission areas EA1, EA2 and EA3 and may be disposed to overlap the light shielding layer BM to be described later. In addition, the second bank layer BN2 may include a metal material and be electrically connected to the common electrodes CE1, CE2 and CE3 of the different light-emitting elements ED1, ED2 and ED3. The light-emitting elements ED1, ED2 and ED3 disposed in different emission areas EA1, EA2 and EA3 are not directly connected to the common electrodes CE1, CE2 and CE3, but may be electrically connected through the second bank layer BN2.

In the manufacturing process of the display device 10, a mask process is desired in order to form the pixel-defining layer forming the emission areas EA1, EA2 and EA3 with an organic material, or form the light-emitting layers EL1, EL2 and EL3 of the light-emitting elements ED1, ED2 and ED3 for each of the emission areas EA1, EA2 and EA3. A structure for mounting a mask in order to perform the mask process or an unnecessarily great area of the non-display area NDA may be desired in the display device 10 in order to control dispersion according to the mask process. When such a mask process is minimized, an unnecessary component such as the structure for mounting the mask may be omitted from the display device 10, and the area of the non-display area NDA for controlling the dispersion may be minimized.

In the display device 10 in an embodiment, by including the bank structure BNS forming the emission areas EA1, EA2 and EA3, the light-emitting layers EL1, EL2 and EL3 and the common electrodes CE1, CE2 and CE3 may be formed through deposition and etching processes rather than the mask process. In addition, as the bank structure BNS have a structure including a tip TIP protruding toward the opening or the emission areas EA1, EA2 and EA3, it is possible to form different layers individually in the different emission areas EA1, EA2 and EA3 even through a deposition process. In an embodiment, even though the light-emitting layers EL1, EL2 and EL3 and the common electrodes CE1, CE2 and CE3 of the light-emitting elements ED1, ED2 and ED3 are formed through a deposition process that does not use the mask, materials deposited by the tip TIP protruding toward the opening or the emission areas EA1, EA2 and EA3 of the third bank layer BN3 may be disconnected from each other with the bank structure BNS interposed therebetween. It is possible to form the different layers individually in the different emission areas EA1, EA2 and EA3 through a process of forming a material for forming a predetermined layer on the entirety of the surface of the display device 10 and then etching and removing a layer formed in unwanted areas, for example. In the display device 10, through the deposition and etching processes without using the mask process, the different light-emitting elements ED1, ED2 and ED3 may be formed for each of the emission areas EA1, EA2 and EA3, the unnecessary component may be omitted from the display device 10, and the area of the non-display area NDA may be minimized.

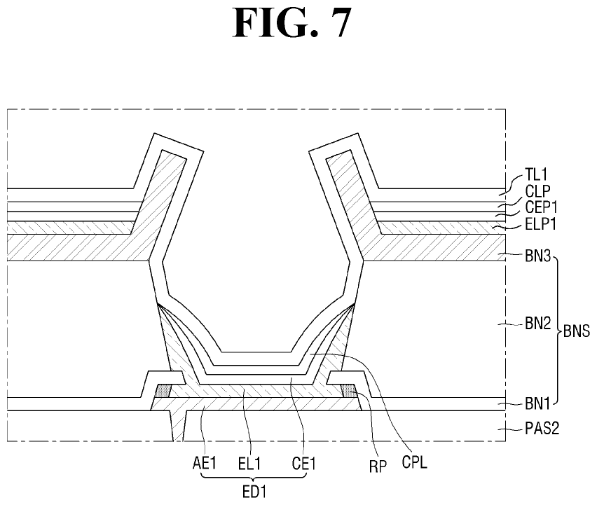

As will be described later, a first inorganic layer TL1, a second inorganic layer TL2 and a third inorganic layer TL3 may be patterned in separate processes, and the patterning process of the inorganic layers TL1, TL2 and TL3 may be repeated several times. When the third bank layer BN3 is exposed in each repeated patterning process, the thickness of the third bank layer BN3 may become thinner, and the tip TIP of the third bank layer BN3 may become thinner. In an embodiment, when the processes of forming the first light-emitting element ED1, the second light-emitting element ED2 and the third light-emitting element ED3 are sequentially performed, the third bank layer BN3 around the third opening is exposed to the most processes and may be in the most vulnerable state, for example. In this case, some of the openings, for example, the tip TIP adjacent to the third opening may not maintain a shape protruding from the sidewall of the second bank layer BN2 and may have a shape bent upward as shown in FIG. 7. When the tip TIP is bent, contact between the common electrodes CE1, CE2 and CE3 of the light-emitting elements ED1, ED2 and ED3 and the sidewall of the second bank layer BN2 may not be smooth. Accordingly, contact resistance between the common electrodes CE1, CE2 and CE3 and the second bank layer BN2 may increase, which may cause a decrease in luminance of some of the light-emitting elements ED1, ED2 and ED3, and thus stains may occur in the displayed image of the display device 10.

In the display device 10 in an embodiment, the third bank layer BN3 may include metal nitride to prevent bending of the tip by increasing structural stability of the tip TIP of the third bank layer BN3 during a manufacturing process. Since the metal nitride has excellent elasticity, the tip TIP including the metal nitride may maintain a protruding shape toward the opening or the emission areas EA1, EA2 and EA3. In addition, since the mechanical strength is excellent, the tip shape may be maintained even with a thin thickness.

In an embodiment, the metal nitride may be titanium nitride (TiN). Titanium nitride (TiN) has relatively high conductivity and may be etched together with aluminum or/and titanium of the second bank layer by dry etching. In addition, since titanium nitride (TiN) has relatively high resistance to fluorine-based etchant, the tip structure may have relatively high stability even in the subsequent undercut structure patterning process.

In the embodiments of FIGS. 5 and 6, the third bank layer BN3 is shown to include or consist of one layer, but the disclosure not limited thereto. The third bank layer BN3 may have a multilayer structure of two or more layers, and may include a double layer, a triple layer, or a plurality of layers including the same or different materials from each other.

In an embodiment, a thickness of the third bank layer BN3 may be in the range of about 100 Å to about 1500 Å. According to an example, the thickness of the third bank layer BN3 may be in the range of about 150 Å to about 1500 Å. According to an example, the thickness of the third bank layer BN3 may be in the range of about 200 Å to about 1000 Å. According to an example, the thickness of the third bank layer BN3 may be in the range of about 250 Å to about 600 Å. When the above range is satisfied, fine patterning may be smoothly performed while securing enough strength for the tip TIP to maintain the structure in the subsequent process.

In an embodiment, the tip TIP of the third bank layer BN3 protruding from the second bank layer BN2 toward the opening or the emission areas EA1, EA2 and EA3 may have a width of about 0.1 micrometer (μm) to about 1.0 μm in the fourth direction DR4. The width of each of the first tip TIP1 and second tip TIP2 may be in the range of about 0.1 μm to about 1.0 μm. According to an example, the width of each of the first tip and second tip may be in the range of about 0.1 μm to about 0.7 μm. According to an example, the width of each of the first tip and second tip may be in the range of about 0.2 μm to about 0.6 μm. When the above range is satisfied, the light-emitting layers and the common electrodes of the emission area are uniformly deposited in the opening, and a region in which the common electrodes contact the sidewall of the second bank layer may be secured.

The tips TIP of the third bank layer BN3 may overlap the common electrodes CE1, CE2 and CE3 in the thickness direction DR3 of the substrate. The first tip may overlap the first common electrode CE1 in the thickness direction DR3, and the second tip may overlap the second common electrode CE2 in the thickness direction DR3. In addition, the tips TIP of the third bank layer BN3 may overlap the light-emitting layers EL1, EL2 and EL3 in the thickness direction DR3 of the substrate perpendicular to the substrate. In addition, the tips TIP of the third bank layer BN3 may overlap the first bank layer BN1 in the thickness direction DR3 of the substrate.

The display device 10 may include patterns which are marks based on the shape and deposition process of the bank structure BNS. The patterns may be formed simultaneously with the light-emitting layers EL1, EL2 and EL3 and the common electrodes CE1, CE2 and CE3 of the light-emitting elements ED1, ED2 and ED3, and may remain on the bank structure BNS. Hereinafter, structures of the light-emitting layers EL1, EL2 and EL3 and the common electrodes CE1, CE2 and CE3 and the patterns will be described.

The light-emitting layers EL1, EL2 and EL3 may be disposed on the pixel electrodes AE1, AE2 and AE3. The light-emitting layers EL1, EL2 and EL3 may be organic light-emitting layers including an organic material, and may be formed on the pixel electrodes AE1, AE2 and AE3 through a deposition process. When the thin-film transistor TFT applies a predetermined voltage of the pixel electrodes AE1, AE2 and AE3 of the light-emitting elements ED1, ED2 and ED3 and the common electrodes CE1, CE2 and CE3 of the light-emitting elements ED1, ED2 and ED3 receive a common voltage or a cathode voltage, holes and electrons may be transferred to the light-emitting layers EL1, EL2 and EL3 through the hole transporting layer and the electron transporting layer, and may be combined with each other in the light-emitting layers EL1, EL2 and EL3 to emit light.

The light-emitting layers EL1, EL2 and EL3 may include a first light-emitting layer EL1, a second light-emitting layer EL2 and a third light-emitting layer EL3, which are disposed in different emission areas EA1, EA2 and EA3. The first light-emitting layer EL1 may be disposed on the first pixel electrode AE1 in the first emission area EA1, the second light-emitting layer EL2 may be disposed on the second pixel electrode AE2 in the second emission area EA2, and the third light-emitting layer EL3 may be disposed on the third pixel electrode AE3 in the third emission area EA3. The first to third light-emitting layers EL1, EL2 and EL3 may be light-emitting layers of the first to third light-emitting elements ED1, ED2 and ED3, respectively. The first light-emitting layer EL1 may be a light-emitting layer emitting red light of a first color, the second light-emitting layer EL2 may be a light-emitting layer emitting green light of a second color, and the third light-emitting layer EL3 may be a light-emitting layer emitting blue light of a third color.

In an embodiment, a portion of the light-emitting layers EL1, EL2 and EL3 of the light-emitting elements ED1, ED2 and ED3 may be disposed between the pixel electrodes AE1, AE2 and AE3 and the first bank layer BN1. The first bank layer BN1 may be disposed on the pixel electrodes AE1, AE2 and AE3 but spaced apart from the top surfaces of the pixel electrodes AE1, AE2 and AE3. The deposition process of the light-emitting layers EL1, EL2 and EL3 may be performed such that a material of the light-emitting layer is deposited in an inclined direction that is not perpendicular to the upper surface of the substrate SUB. Therefore, the light-emitting layers EL1, EL2 and EL3 may be disposed to fill the upper surfaces of the pixel electrodes AE1, AE2 and AE3 exposed to the openings and the space between the pixel electrodes AE1, AE2 and AE3 and the first bank layer BN1.

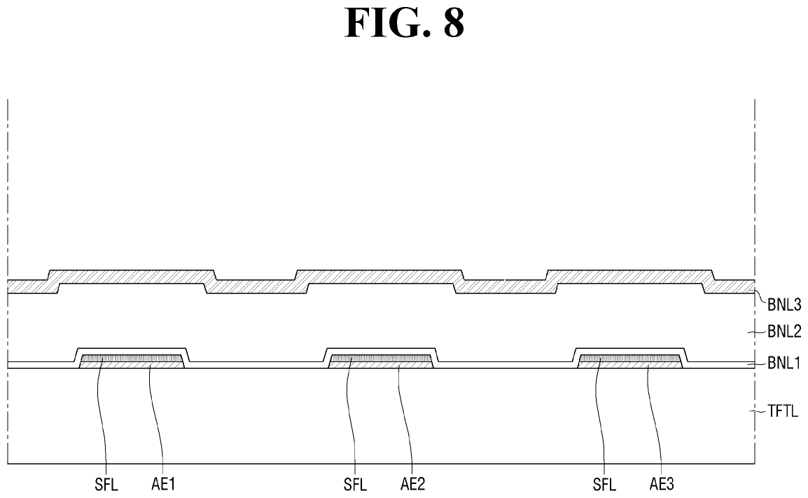

In the manufacturing process of the display device 10, the sacrificial layer SFL (refer to FIG. 8) may be disposed between the first bank layer BN1 and the pixel electrodes AE1, AE2 and AE3, and then the light-emitting layers EL1, EL2 and EL3 may be disposed in areas where the sacrificial layer SFL is partially removed. Accordingly, the lower surface of the first bank layer BN1 may be spaced apart from the pixel electrodes AE1, AE2 and AE3. However, the sacrificial layer SFL may remain as a residual pattern RP in an area between the first bank layer BN1 and the pixel electrodes AE1, AE2 and AE3. An area between the first bank layer BN1 and the pixel electrodes AE1, AE2 and AE3 may be filled with a portion of the residual pattern RP and the light-emitting layers EL1, EL2 and EL3.

The display device 10 in an embodiment may include a plurality of organic patterns ELP1, ELP2 and ELP3 including the same materials as that of the light-emitting layers EL1, EL2 and EL3, respectively, and disposed on the bank structure BNS. Since the light-emitting layers EL1, EL2 and EL3 are formed through a process of depositing materials on the entirety of the surface of the display device 10, materials forming the light-emitting layers EL1, EL2 and EL3 may be deposited on the bank structure BNS as well as in the emission areas EA1, EA2 and EA3 of the bank structure BNS.

In an embodiment, the display device 10 may include organic patterns ELP1, ELP2 and ELP3 disposed above the bank structure BNS, for example. The organic patterns ELP1, ELP2 and ELP3 may include a first organic pattern ELP1, a second organic pattern ELP2 and a third organic pattern ELP3, which are disposed on the third bank layer BN3 of the bank structure BNS.

The first organic pattern ELP1 may include the same material as that of the first light-emitting layer EL1 of the first light-emitting element ED1. The second organic pattern ELP2 may include the same material as that of the second light-emitting layer EL2 of the second light-emitting element ED2, and the third organic pattern ELP3 may include the same material as that of the third light-emitting layer EL3 of the third light-emitting element ED3. The organic patterns ELP1, ELP2 and ELP3 may be formed in the forming processes of the light-emitting layers EL1, EL2 and EL3 including the same materials as that of the organic patterns ELP1, ELP2 and ELP3, respectively.

The first organic pattern ELP1, the second organic pattern ELP2, and the third organic pattern ELP3 may be directly disposed on the third bank layer BN3 of the bank structure BNS. The organic patterns ELP1, ELP2 and ELP3 may be formed in the same processes as that of the light-emitting layers EL1, EL2 and EL3 including the same materials as that of the organic patterns ELP1, ELP2 and ELP3, respectively, and may be disposed adjacent to the emission areas EA1, EA2 and EA3 in which the respective light-emitting layers EL1, EL2 and EL3 are disposed. In an embodiment, the first organic pattern ELP1 may be disposed on the third bank layer BN3 while surrounding the first opening around the first emission area EA1 or the first opening, for example. The second organic pattern ELP2 may be disposed on the third bank layer BN3 while surrounding the second opening around the second emission area EA2 or the second opening, and the third organic pattern ELP3 may be disposed on the third bank layer BN3 while surrounding the third opening around the third emission area EA3 or the third opening.

Such organic patterns ELP1, ELP2 and ELP3 may be traces formed while the deposited materials are disconnected from the light-emitting layers EL1, EL2 and EL3 rather than being connected to the light-emitting layers EL1, EL2 and EL3 because the bank structure BNS includes the tips TIP. The light-emitting layers EL1, EL2 and EL3 may be formed in the openings, and the organic patterns ELP1, ELP2 and ELP3 and the light-emitting layers EL1, EL2 and EL3 may be disconnected from each other by the tips TIP of the bank structure BNS. The light-emitting layers EL1, EL2 and EL3 are formed through the deposition process that does not use the mask, and accordingly, materials of the light-emitting layers EL1, EL2 and EL3 may be entirely formed on the bank structure BNS, and the organic patterns ELP1, ELP2 and ELP3 may be formed by patterning these materials around the emission areas EA1, EA2 and EA3 or the openings.

The common electrodes CE1, CE2 and CE3 may be disposed on the light-emitting layers EL1, EL2 and EL3. The common electrodes CE1, CE2 and CE3 may include a transparent conductive material to emit light generated from the light-emitting layers EL1, EL2 and EL3. The common electrodes CE1, CE2 and CE3 may receive a common voltage or a low-potential voltage. When the pixel electrodes AE1, AE2 and AE3 receive a voltage corresponding to the data voltage and the common electrodes CE1, CE2 and CE3 receive the low-potential voltage, a potential difference is formed between the pixel electrodes AE1, AE2 and AE3 and the common electrodes CE1, CE2 and CE3, so that the light-emitting layers EL1, EL2 and EL3 may emit light.

The common electrodes CE1, CE2 and CE3 may include a first common electrode CE1, a second common electrode CE2 and a third common electrode CE3, which are disposed in the different emission areas EA1, EA2 and EA3. The first common electrode CE1 may be disposed on the first light-emitting layer EL1 in the first emission area EA1, the second common electrode CE2 may be disposed on the second light-emitting layer EL2 in the second emission area EA2, and the third common electrode CE3 may be disposed on the third light-emitting layer EL3 in the third emission area EA3.

In an embodiment, the common electrodes CE1, CE2 and CE3 may be disposed on the sidewall of the second bank layer BN2. Similar to the light-emitting layers EL1, EL2 and EL3, the common electrodes CE1, CE2 and CE3 may also be formed through a deposition process. The deposition process of the common electrodes CE1, CE2 and CE3 may be performed such that the electrode material is deposited in an inclined direction rather than a direction perpendicular to the upper surface of the substrate SUB. Accordingly, the common electrodes CE1, CE2 and CE3 may be disposed on the sidewall of the second bank layer BN2 below the tip TIP of the third bank layer BN3. The common electrodes CE1, CE2 and CE3 may be in direct contact with the sidewall of the second bank layer BN2. The common electrodes CE1, CE2 and CE3 of the different light-emitting elements ED1, ED2 and ED3 may be in direct contact with the second bank layer BN2, respectively, and each of the common electrodes CE1, CE2 and CE3 may be electrically connected to each other. Unlike the pixel electrodes AE1, AE2 and AE3, the common electrodes CE1, CE2 and CE3 are not classified according to a plurality of pixels, but may be implemented in an electrode form electrically common to all pixels.

In an embodiment, the common electrodes CE1, CE2 and CE3 may be formed under lower surfaces of the tips TIP of the third bank layer BN3. One end and the other end of the common electrodes CE1, CE2 and CE3 may contact the sidewall of the second bank layer BN2. A maximum distance from the substrate SUB to each of the common electrodes CE1, CE2 and CE3 may be smaller than a maximum distance from the substrate SUB to the second bank layer BN2.

Although not shown in the drawing, the light-emitting layers EL1, EL2 and EL3 may be in direct contact with the sidewall of the second bank layer BN2. A contact area between the common electrodes CE1, CE2 and CE3 and the sidewall of the second bank layer BN2 may be greater than a contact area between the light-emitting layers EL1, EL2 and EL3 and the sidewall of the second bank layer BN2. Each of the deposition processes of the common electrodes CE1, CE2 and CE3 and the light-emitting layers EL1, EL2 and EL3 may be performed so that the materials of the common electrodes CE1, CE2 and CE3 and the light-emitting layers EL1, EL2 and EL3 are deposited in the direction inclined with respect to the upper surface of the substrate SUB, and areas of the common electrodes CE1, CE2 and CE3 and the light-emitting layers EL1, EL2 and EL3 disposed on the sidewall of the second bank layer BN2 may change depending on an inclined angle. In an embodiment, the deposition process of the common electrodes CE1, CE2 and CE3 may be performed in a more inclined direction than the deposition process of the light-emitting layers EL1, EL2 and EL3. The common electrodes CE1, CE2 and CE3 may be disposed to have a greater area than the light-emitting layers EL1, EL2 and EL3 on the sidewalls of the second bank layer BN2 or may be disposed up to a greater height on the sidewalls of the second bank layer BN2 than the light-emitting layers EL1, EL2 and EL3. Since the common electrodes CE1, CE2 and CE3 of the different light-emitting elements ED1, ED2 and ED3 are electrically connected to each other through the second bank layer BN2, it may be advantageous that the common electrodes CE1, CE2 and CE3 contact the second bank layer BN2 in a greater area.

The display device 10 in an embodiment may include a plurality of electrode patterns CEP1, CEP2 and CEP3 including the same materials as that of the common electrodes CE1, CE2 and CE3 and disposed on the bank structure BNS. Since the common electrodes CE1, CE2 and CE3 are formed through a process of depositing a material on the entirety of the surface of the display device 10, the material forming the common electrodes CE1, CE2 and CE3 may also be deposited on the bank structure BNS as well as in the emission area.

The display device 10 may include electrode patterns CEP1, CEP2 and CEP3 disposed on the bank structure BNS. The electrode patterns CEP1, CEP2 and CEP3 may include a first electrode pattern CEP1, a second electrode pattern CEP2, and a third electrode pattern CEP3 disposed on the third bank layer BN3 of the bank structure BNS.

In an embodiment, the first electrode pattern CEP1, the second electrode pattern CEP2, and the third electrode pattern CEP3 may be directly disposed on the first organic pattern ELP1, the second organic pattern ELP2, and the third organic pattern ELP3, respectively, for example. An arrangement relationship between the electrode patterns CEP1, CEP2 and CEP3 and the organic patterns ELP1, ELP2 and ELP3 may be the same as an arrangement relationship between the light-emitting layers EL1, EL2 and EL3 and the common electrodes CE1, CE2 and CE3 of the light-emitting elements ED1, ED2, and ED3. Such electrode patterns CEP1, CEP2 and CEP3 may be traces formed while the deposited materials are disconnected from the common electrodes CE1, CE2 and CE3 rather than being connected to the common electrodes CE1, CE2 and CE3 because the bank structure BNS includes the tips TIP. In the display device 10, the common electrodes CE1, CE2 and CE3 may be individually formed in different areas even in the deposition process that does not use the mask by the tips TIP of the bank structure BNS.

Capping layers CPL may be disposed on the common electrodes CE1, CE2 and CE3. The capping layers CPL may include an inorganic insulating material to cover the light-emitting elements ED1, ED2 and ED3 and patterns disposed on the bank structure BNS. The capping layers CPL may prevent damage to the light-emitting elements ED1, ED2 and ED3 from external air and prevent the patterns disposed on the bank structure BNS from being peeled off during the manufacturing processes of the display device 10. In an embodiment, the capping layer CPL may include aluminum oxide, titanium oxide, tantalum oxide, hafnium oxide, zinc oxide, silicon oxide, silicon nitride, and/or silicon oxynitride.

The display device 10 may include capping patterns CLP disposed above the bank structure BNS. The capping patterns CLP may be directly disposed on the first electrode pattern CEP1, the second electrode pattern CEP2, and the third electrode pattern CEP3 disposed on the third bank layer BN3 of the bank structure BNS. An arrangement relationship between the capping patterns CLP and the electrode patterns CEP1, CEP2 and CEP3 may be the same as an arrangement relationship between the common electrodes CE1, CE2 and CE3 of the light-emitting elements ED1, ED2 and ED3 and the capping layers CPL. Such capping pattern CLP may be a trace formed when the deposited material is disconnected from the capping layer CPL since the bank structure BNS includes the tip TIP.

The plurality of organic patterns ELP1, ELP2 and ELP3, the electrode patterns CEP1, CEP2 and CEP3, and the capping patterns CLP may be disposed on the bank structure BNS, and may be disposed to surround the emission areas EA1, EA2 and EA3 or the openings. A stacked structure of the organic patterns ELP1, ELP2 and ELP3, the electrode patterns CEP1, CEP2 and CEP3, and the capping patterns CLP disposed around the emission areas EA1, EA2 and EA3 may be partially etched in the manufacturing processes of the display device 10, such that a pattern shape may be changed. Accordingly, portions of an upper surface of the third bank layer BN3 of the bank structure BNS may not be covered by the organic patterns ELP1, ELP2 and ELP3, the electrode patterns CEP1, CEP2 and CEP3, and the capping patterns CLP.

The thin-film encapsulation layer TFEL may be disposed on the light-emitting elements ED1, ED2 and ED3 and the bank structure BNS, and may cover the plurality of light-emitting elements ED1, ED2 and ED3 and the bank structure BNS. The thin-film encapsulation layer TFEL may include at least one inorganic layer to prevent oxygen or moisture from being permeated into the light-emitting element layer EML. The thin-film encapsulation layer TFEL may include at least one organic layer to protect the light-emitting element layer EML from particles such as dust.

In an embodiment, the thin-film encapsulation layer TFEL may include a first encapsulation layer TFE1, a second encapsulation layer TFE2 and a third encapsulation layer TFE3, which are sequentially stacked. The first encapsulation layer TFE1 and the third encapsulation layer TFE3 may be inorganic encapsulation layers, and the second encapsulation layer TFE2 disposed therebetween may be an organic encapsulation layer.

Each of the first encapsulation layer TFE1 and the third encapsulation layer TFE3 may include one or more inorganic insulating materials. The inorganic insulating materials may include any one of silicon oxide, silicon nitride, and silicon oxynitride, and may include aluminum oxide, titanium oxide, tantalum oxide, hafnium oxide, zinc oxide, silicon oxide, silicon nitride and/or silicon oxynitride, for example.

The second encapsulation layer TFE2 may include a polymer-based material. The polymer-based material may include an acrylic resin, an epoxy-based resin, polyimide and polyethylene. In an embodiment, the second encapsulation layer TFE2 may include an acrylic resin, e.g., polymethyl methacrylate, polyacrylic acid, or the like, for example. The second encapsulation layer TFE2 may be formed by curing a monomer or applying a polymer.

The first encapsulation layer TFE1 may be disposed on the light-emitting elements ED1, ED2 and ED3, the plurality of patterns and the bank structure BNS. The first encapsulation layer TFE1 may include a first inorganic layer TL1, a second inorganic layer TL2 and a third inorganic layer TL3, which are disposed to correspond to the different light emission areas EA1, EA2 and EA3, respectively.

The first inorganic layer TL1, the second inorganic layer TL2 and the third inorganic layer TL3 may respectively include an inorganic insulating material to cover the light-emitting elements ED1, ED2 and ED3. The first inorganic layer TL1, the second inorganic layer TL2 and the third inorganic layer TL3 may prevent the light-emitting elements ED1, ED2 and ED3 from being damaged from the external air, and the patterns disposed on the bank structure BNS may be prevented from being delaminated during the fabricating process of the display device 10. In an embodiment, the first inorganic layer TL1, the second inorganic layer TL2 and the third inorganic layer TL3 may include aluminum oxide, titanium oxide, tantalum oxide, hafnium oxide, zinc oxide, silicon oxide, silicon nitride and/or silicon oxynitride.

The first inorganic layer TL1, the second inorganic layer TL2 and the third inorganic layer TL3 may be disposed to cover the organic patterns ELP1, ELP2 and ELP3, the electrode patterns CEP1, CEP2 and CEP3 and the capping pattern CLP. The first inorganic layer TL1, the second inorganic layer TL2 and the third inorganic layer TL3 may be formed by chemical vapor deposition (CVD), and thus may be formed to have a uniform thickness along a step difference of the layers that are deposited. In an embodiment, the first inorganic layer TL1, the second inorganic layer TL2 and the third inorganic layer TL3 may form a thin-film even below the undercut due to the tip TIP of the bank structure BNS, for example.

The first inorganic layer TL1 may be disposed on the first light-emitting element ED1 and the first electrode pattern CEP1. The first inorganic layer TL1 may be disposed along the first light-emitting element ED1, the capping layer CPL and the sidewall adjacent to the first common electrode CE1 of the second bank layer BL2 to cover the first light-emitting element ED1, the capping layer CPL, and may be disposed to cover the first organic pattern ELP1, the first electrode pattern CEP1 and the capping pattern CLP. However, the first inorganic layer TL1 may be disposed only on the first opening and the bank structure BNS near the first opening without being overlapped with the second opening and the third opening.

The second inorganic layer TL2 may be disposed on the second light-emitting element ED2 and the second electrode pattern CEP2. The second inorganic layer TL2 may be disposed along the second light-emitting element ED2, the capping layer CPL and the sidewall adjacent to the second common electrode CE2 of the second bank layer BL2 to cover the second light-emitting element ED2, the capping layer CPL and the sidewall adjacent to the second common electrode CE2 of the second bank layer BL2, and may be disposed to cover the second organic pattern ELP2, the second electrode pattern CEP2 and the capping pattern CLP. However, the second inorganic layer TL2 may be disposed only on the second opening and the bank structure BNS near the second opening without being overlapped with the first opening and the third opening.

The third inorganic layer TL3 may be disposed on the third light-emitting element ED3 and the third electrode pattern CEP3. The third inorganic layer TL3 may be disposed along the third light-emitting element ED3, the capping layer CPL and the sidewall adjacent to the third common electrode CE3 of the second bank layer BL2 to cover the third light-emitting element ED3, the capping layer CPL and the sidewall adjacent to the third common electrode CE3 of the second bank layer BL2, and may be disposed to cover the third organic pattern ELP3, the third electrode pattern CEP3 and the capping pattern CLP. However, the third inorganic layer TL3 may be disposed only on the third opening and the bank structure BNS near the third opening without being overlapped with the first opening and the second opening.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. Accordingly, the first to third inorganic layers TL1, TL2 and TL3 may be disposed to cover different electrode patterns CEP1, CEP2 and CEP3 and organic patterns ELP1, ELP2 and ELP3, respectively. Each of the first inorganic layer TL1, the second inorganic layer TL2, and the third inorganic layer TL3 may have a greater area than each of the openings of the bank structure BNS in a plan view. The first inorganic layer TL1, the second inorganic layer TL2, and the third inorganic layer TL3 may be spaced apart from each other on the bank structure BNS. Accordingly, portions of the third bank layer BN3 of the bank structure BNS may not overlap the inorganic layers TL1, TL2 and TL3, and portions of the upper surface of the third bank layer BN3 may be exposed without being covered by the inorganic layers TL1, TL2 and TL3 in the spaces between the first to third inorganic layers. A portion of the third bank layer BN3 may be in direct contact with the second encapsulation layer TFE2 of the thin-film encapsulation layer TFEL.

The light shielding layer BM may be disposed on the thin-film encapsulation layer TFEL. The light shielding layer BM may define a plurality of holes OPT1, OPT2 and OPT3 defined to overlap the emission areas EA1, EA2 and EA3. In an embodiment, the first hole OPT1 may be defined to overlap the first emission area EA1, for example. The second hole OPT2 may be defined to overlap the second emission area EA2, and the third hole OPT3 may be defined to overlap the third emission area EA3. An area or size of each of the holes OPT1, OPT2 and OPT3 may be greater than that of the emission areas EA1, EA2 and EA3. As the holes OPT1, OPT2 and OPT3 of the light shielding layer BM are greater than the emission areas EA1, EA2 and EA3, light emitted from the emission areas EA1, EA2 and EA3 may be visible to a user from the side as well as the front surface of the display device 10.

The light shielding layer BM may include a light absorbing material. In an embodiment, the light shielding layer BM may include an inorganic black pigment or an organic black pigment, for example. The inorganic black pigment may be carbon black, and the organic black pigment may include, but is not limited to, at least one of lactam black, perylene black or aniline black. The light shielding layer BM may prevent visible light from being permeated among the first to third light emission areas EA1, EA2 and EA3, thereby preventing a color combination from occurring to improve a color reproduction rate of the display device 10.

The display device 10 may include a plurality of color filters CF1, CF2 and CF3 disposed on the emission areas EA1, EA2 and EA3. The plurality of color filters CF1, CF2 and CF3 may be disposed to respectively correspond to the emission areas EA1, EA2 and EA3. In an embodiment, the color filters CF1, CF2 and CF3 may be disposed on the light shielding layer BM that defines a plurality of holes OPT1, OPT2 and OPT3 disposed to correspond to the emission areas EA1, EA2 and EA3, for example. The holes of the light shielding layer may be defined to overlap the emission areas EA1, EA2 and EA3 or the openings of the bank structures BNS, and may form light output areas to which light emitted from the emission areas EA1, EA2 and EA3 is output. Each of the color filters CF1, CF2 and CF3 may have an area greater than that of the hole of the light shielding layer BM, and each of the color filters CF1, CF2 and CF3 may completely cover the light output area defined by the hole.

The color filters CF1, CF2 and CF3 may include a first color filter CF1, a second color filter CF2 and a third color filter CF3, which are respectively disposed to correspond to the different emission areas EA1, EA2 and EA3. The color filters CF1, CF2 and CF3 may include a colorant, such as a dye or a pigment, which absorbs light of a wavelength range other than light of a predetermined wavelength range, and may be disposed to correspond to a color of light emitted from each of the emission areas EA1, EA2 and EA3. In an embodiment, the first color filter CF1 may be a red color filter disposed to overlap the first emission area EA1, transmitting only the first light of a red color, for example. The second color filter CF2 may be a green color filter disposed to overlap the second emission area EA2, transmitting only the second light of a green color. The third color filter CF3 may be a blue color filter disposed to overlap the third emission area EA3, transmitting only the third light of a blue color.

The plurality of color filters CF1, CF2 and CF3 may be spaced apart from one another on the light shielding layer BM. The color filters CF1, CF2 and CF3 may respectively cover the holes OPT1, OPT2 and OPT3 of the light shielding layer BM, and may have an area that is greater than that of the hole and spaced apart from the other color filters on the light shielding layer BM but is not limited thereto. The color filters CF1, CF2 and CF3 may be disposed to partially overlap other adjacent color filters CF1, CF2 and CF3. The different color filters CF1, CF2 and CF3 do not overlap the emission areas EA1, EA2 and EA3, and may overlap one another on the light shielding layer BM that will be described later. The display device 10 may reduce intensity of reflective light due to external light as the color filters CF1, CF2 and CF3 are disposed to overlap one another. Furthermore, a color sense of the reflective light due to the external light may be controlled by adjusting layouts, shapes, areas of the color filters CF1, CF2 and CF3 on the plan view.

An overcoat layer OC may be disposed on the color filters CF1, CF2 and CF3 to planarize upper ends of the color filters CF1, CF2 and CF3. The overcoat layer OC may be a colorless light-transmissive layer that does not have a color of a visible light band. In an embodiment, the overcoat layer OC may include a colorless light-transmissive organic material such as an acrylic resin, for example.

Hereinafter, a fabricating process of the display device 10 in an embodiment of the disclosure will be described with reference to the other drawings.

FIGS. 8 to 15 are cross-sectional views illustrating a fabricating process of a display device. FIGS. 8 to IS schematically illustrate a process of forming a bank structure BNS as a light-emitting element layer EML of the display device 10, light-emitting elements ED and a thin-film encapsulation layer TFEL. Hereinafter, a process of forming each layer with respect to a fabricating process of the display device 10 will be omitted, and a formation order of each layer will be described.

Referring to FIG. 8, a plurality of pixel electrodes AE1, AE2 and AE3 spaced apart from each other, a sacrificial layer SFL and a plurality of bank material layers BNL1, BNL2 and BNL3 are formed on a thin-film transistor layer TFTL.

Although not shown in the drawing, the thin-film transistor layer TFTL may be disposed on a substrate SUB, and a structure of the thin-film transistor layer TFTL is the same as that described above with reference to FIG. 5. A detailed description of the thin-film transistor layer TFTL will be omitted.

The sacrificial layer SFL may be disposed on the pixel electrodes AE1, AE2 and AE3. The sacrificial layer SFL may be disposed on the pixel electrodes AE1, AE2 and AE3, and then partially removed in a subsequent process to define spaces in which the light-emitting layers EL1, EL2 and EL3 are disposed. The sacrificial layer SFL may prevent the upper surfaces of the pixel electrodes AE1, AE2 and AE3 from being in contact with the first bank layer BN1, and may be removed to define spaces between the pixel electrodes AE1, AE2 and AE3 and the first bank layer BN1. In an embodiment, the sacrificial layer SFL may include an oxide semiconductor. In an embodiment, the sacrificial layer SFL may include at least one of indium gallium zinc oxide (“IGZO”), zinc tin oxide (“ZTO”), and indium tin oxide (“IZO”), for example.

Bank material layers BNL1, BNL2 and BNL3 may be disposed on the sacrificial layer SFL. The first bank material layer BNL1 may be disposed to cover an entirety of the sacrificial layer SFL and the thin-film transistor layer TFTL, and the second and third material layers BNL2 and BNL3 may be disposed to cover an entirety of the first bank material layer BNL1. The bank material layers BNL1, BNL2 and BNL3 may be partially etched in a subsequent process to respectively form bank layers BN1, BN2 and BN3 of the bank structures BNS illustrated in FIG. 5.

Next, referring to FIG. 9, a photoresist PR is formed on the bank material layers BNL1, BNL2 and BNL3, and a first etching process is performed to etch a portion of the bank material layers BNL1, BNL2 and BNL3 using a photoresist PR as a mask to define a first hole HOL1.

The photoresist PR may be spaced apart from another photoresist PR on bank material layers BNL1, BNL2 and BNL3. The photoresists PR may be disposed on the third bank material layer BNL3 to expose a portion overlapped with the first pixel electrode AE1.

In an embodiment, the first etching process may be performed by dry etching. As the first etching process is performed by dry etching, the bank material layers BNL1, BNL2 and BNL3 including different materials may be anisotropically etched. In this process, the bank material layers BNL1, BNL2 and BNL3 may be etched together to partially expose the sacrificial layer SFL therebelow. The first hole HOL1 may be defined in an area overlapped with the pixel electrodes AE1, AE2 and AE3, and the first hole HOL1 may define openings of the bank structure BNS.

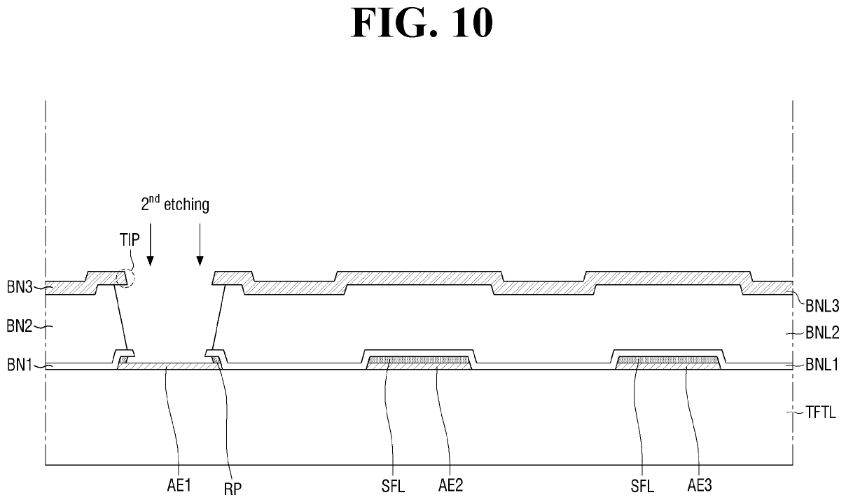

Next, referring to FIG. 10, a second etching process is performed to remove the sacrificial layer SFL disposed on the first pixel electrode AE1. In an embodiment, the sacrificial layer SFL may include an oxide semiconductor layer, and the second etching process may be performed by wet etching. In this process, as the sacrificial layer SFL is removed, the bank material layers BNL1, BNL2 and BNL3 may be isotropically etched in the first hole HOL1. The etch rate of the second bank material layer BNL2 among the bank material layers BNL1, BNL2 and BNL3 may be faster than that of the other bank material layers, and the sidewalls of the first and third bank material layers BNL1 and BNL3 may be formed to protrude further than the sidewall of the second bank material layer BNL2. The sidewall of the third bank material layer BNL3 may protrude further than the sidewall of the second bank material layer BNL2 toward the first hole HOL1 to form a tip TIP, and an undercut may be formed therebelow. The first hole HOL1 may define a first opening or a first emission area EA1 by the second etching process.

A portion of the sacrificial layer SFL exposed by the first hole HOL1 and a portion of the sacrificial layer SFL between the first bank material layer BNL1 and the first pixel electrode AE1 may be removed. However, the sacrificial layer SFL may not be completely removed, and a portion of the residual pattern RP may remain between the first bank material layer BNL1 and the first pixel electrode AE1. As a portion exposed after the sacrificial layer SFL is removed, a space may be formed between the first pixel electrode AE1 and the first bank material layer BNL1 disposed thereon. In a subsequent process, the first light-emitting layer EL1 disposed on the first pixel electrode AE1 may be formed to fill the space.

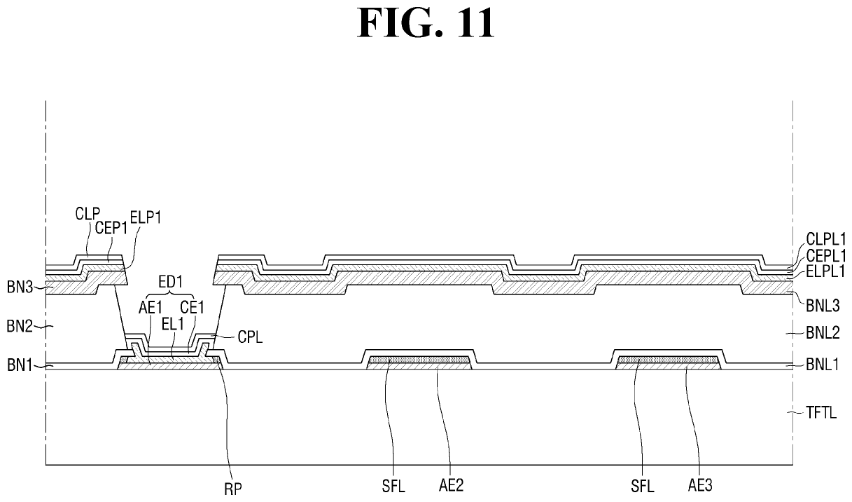

Next, referring to FIG. 11, the first light-emitting layer EL1, the first common electrode CE1 and the capping layer CPL are deposited on the first pixel electrode AE1, and the first light-emitting element ED1 is formed. The first light-emitting element layer EL1 and the first common electrode CE1 may be formed in the first opening, and materials forming the first light-emitting layer EL1 and the first common electrode CE1 in the deposition process are also deposited on the third bank material layers BNL3 to form a plurality of patterns and a pattern material layer. In an embodiment, some of the materials may be deposited on the third bank material layer BNL3 to form a first organic pattern ELP1, a first electrode pattern CEP1, a first organic pattern material layer ELPL1 and a first electrode pattern material layer CEPL1, for example. A portion of the capping layer CPL may be disposed in the first opening or on the first emission area EA1 to cover the first light-emitting element ED1, and another portion of the capping layer CPL may be disposed on the third bank layer BN3 to cover the first organic pattern ELP1 and the first electrode pattern CEP1. A capping material layer CLPL1 may be disposed on the third bank material layers BNL3 to cover the first organic pattern material layer ELPL1 and the first electrode pattern material layer CEPL1. The structure of the first light-emitting layer EL1, the first common electrode CE1, the first organic pattern ELP1 and the first electrode pattern CEP1 is the same as that described above.

The first light-emitting layer EL1 and the first common electrode CE1 may be formed through a deposition process. The materials of the first opening may not be actively deposited due to the tip TIP of the third bank material layer BNL3. However, since the materials of the first light-emitting layer EL1 and the first common electrode CE1 are deposited in an inclined direction that is not perpendicular to the upper surface of the substrate, deposition may be performed even in an area covered by the tip TIP of the third bank material layer BNL3.

In an embodiment, the deposition process for forming the first light-emitting layer EL1 may be performed such that the materials are deposited in a direction that is not perpendicular to the upper surface of the first pixel electrode AE1 in a direction inclined at a first angle, for example. In an embodiment, the deposition of the material in the process of forming the light-emitting layers EL1, EL2 and EL3 may be performed by being inclined at an angle of about 45° to about 50° from the upper surfaces of the pixel electrodes AE1, AE2 and AE3. The first light-emitting layer EL1 may be formed to fill the space between the first pixel electrode AE1 and the first bank material layer BNL1 and may be also formed in the area covered by the tip TIP of the third bank material layer BNL3. In an embodiment, the first light-emitting layer EL1 may be an area covered by the tip TIP, and be partially disposed on the sidewall of the second bank material layer BNL2, for example.

The deposition process of forming the first common electrode CE1 may be performed such that the materials are deposited in a direction that is not perpendicular to the upper surface of the first pixel electrode AE1 in a direction inclined at a second angle, for example. In an embodiment, the deposition of the material in the process of forming the common electrodes CE1, CE2 and CE3 may be performed by being inclined at an angle of 30° or less from the upper surfaces of the pixel electrodes AE1, AE2 and AE3. The first common electrode CE1 may be disposed on the first light-emitting layer EL1, and may be also formed in the area covered by the tip TIP of the third bank material layer BNL3. In an embodiment, the first common electrode CE1 is an area covered by the tip TIP, and may be partially disposed on the sidewall of the second bank material layer BNL2, for example.

The deposition process of forming the common electrodes CE1, CE2 and CE3 may be performed by being inclined to be relatively closer to a horizontal direction than the deposition process of forming the light-emitting layers EL1, EL2 and EL3. The second inclination may be smaller than the first inclination. Therefore, the common electrodes CE1, CE2 and CE3 may have a contact area with the sidewall of the second bank layer BN2 or the second bank material layer BNL2, which is greater than that of the light-emitting layers EL1, EL2 and EL3. In an alternative embodiment, the common electrodes CE1, CE2 and CE3 may be deposited to reach a higher position from the sidewall of the second bank layer BN2 or the second bank material layer BNL2 than the light-emitting layers EL1, EL2 and EL3. The different common electrodes CE1, CE2 and CE3 may be electrically connected to one another in contact with the second bank layer BN2 or the second bank material layer BNL2 having relatively high conductivity.

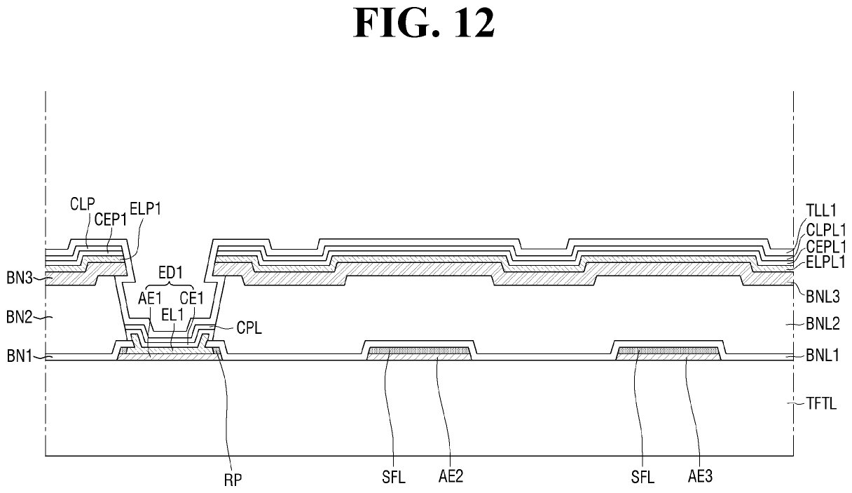

Next, referring to FIG. 12, a first inorganic material layer TLL1 covering the first light-emitting element ED1 and the capping layer CPL is formed. Unlike the light-emitting layers EL1, EL2 and EL3 and the common electrodes CE1, CE2 and CE3, the first inorganic material layer TLL1 may be performed through a chemical vapor deposition (“CVD”) process, and the first inorganic material layer TLL1 may form a uniform film regardless of the step difference of the deposited portion. The first inorganic material layer TLL1 may be formed to completely cover outer surfaces of the first light-emitting element ED1, the bank material layers BNL1, BNL2 and BNL3 and the capping layers CPL. In particular, the first inorganic material layer TLL1 may also be deposited under the tip TIP of the third bank material layer BNL3.

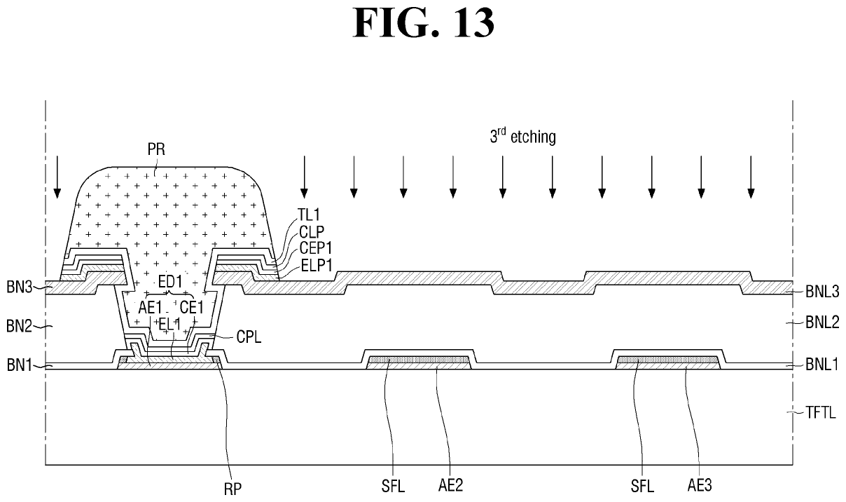

Next, referring to FIG. 13, a photoresist PR having a mask pattern is formed on the first inorganic material layer TLL1, and a third etching process is performed to remove the first organic pattern material layer ELPL1, the first electrode pattern material layer CEPL1, the capping material layer CLPL1, and the first inorganic material layer TLL1 that are not covered by the mask pattern and are disposed on the bank material layers BNL1, BNL2 and BNL3.

In this process, the photoresist PR may be disposed to overlap the first opening or the first light-emitting element ED1. The first organic pattern material layer ELPL1, the first electrode pattern material layer CEPL1, the capping material layer CLPL1, and the first inorganic material layer TLL1 disposed on the bank material layers BNL1, BNL2 and BNL3 may be removed except for the first opening or around the first light-emitting element ED1. In this process, the area except the first opening or the periphery of the first light-emitting element ED1 of the upper surface of the third bank material layer BNL3 may be exposed.

In an embodiment, the third etching process for removing the first inorganic material layer TLL1 disposed on the bank material layers BNL1, BNL2 and BNL3 may be performed as a dry etching process through fluorine (F)-based etchant. The third etching process may remove the first inorganic material layer TLL1 that is not covered by the mask pattern and an etchant which does not etch the third bank layer BN3 or the third bank material layer BNL3 including metal nitride may be used. The fluorine-based etchant may etch the first inorganic material layer TLL1 including silicon, but not etch the third bank layer BN3 or the third bank material layer BNL3 including metal nitride.

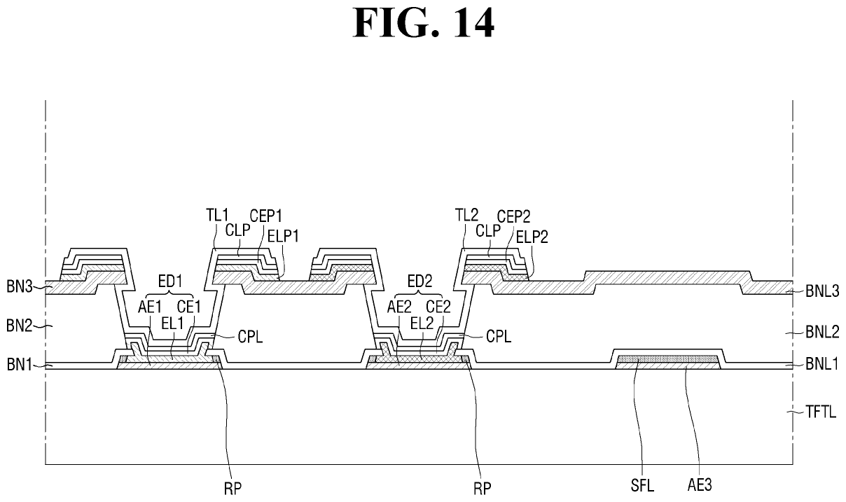

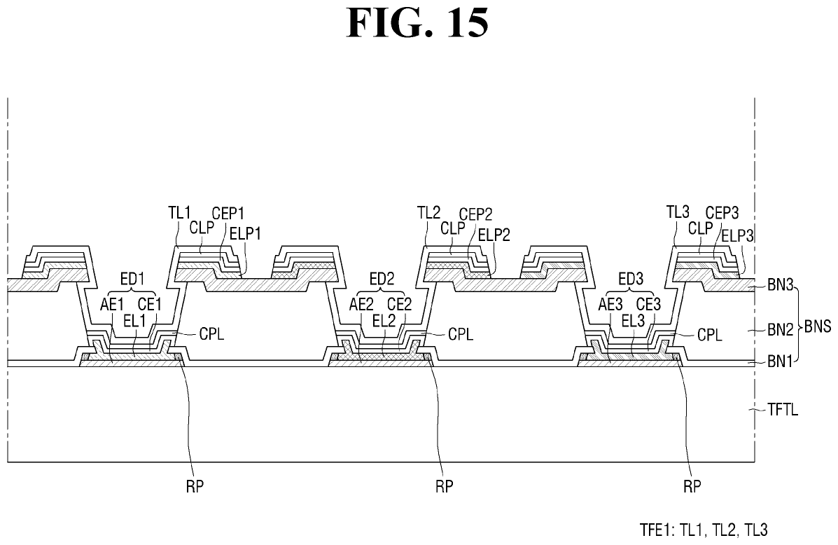

Through the above processes, the first inorganic layer TL1 covering the first light-emitting element ED1, the first organic pattern ELP1, the first electrode pattern CEP1 and the first capping layer CPL may be formed. Referring to FIGS. 14 and 15, processes similar to those described above may be repeated to form the second light-emitting element ED2, the third light-emitting element ED3, the second and third organic patterns ELP2 and ELP3, the second and third electrode patterns CEP2 and CEP3, the second inorganic layer TL2 and the third inorganic layer TL3.

After forming the first light-emitting element ED1, the third etching process of etching the inorganic layers TL1, TL2 and TL3 in the process of forming the second light-emitting element ED2 and the third light-emitting element ED3 may be repeated, and in this repeated third etching process, the tip TIP of the third bank material layer BNL3 may not be bent and maintain its shape. The display device 10 may include tips TIP uniformly formed in the bank structure BNS to sufficiently secure a contact area between the common electrodes CE1, CE2 and CE3 of the respective light-emitting elements ED1, ED2 and ED3 and the second bank layer BN2 in each of the emission areas EA1, EA2 and EA3 and reduce luminance difference between the light-emitting elements ED1, ED2 and ED3.

Subsequently, although not shown, the display device 10 is fabricated by forming the light-emitting elements ED1, ED2 and ED3 and forming a second encapsulation layer TFE2 and a third encapsulation layer TFE3 of the thin-film encapsulation layer TFEL, a light shielding layer BM, a color filter layer CFL and an overcoat layer OC on the bank structure BNS. The structure of the thin-film encapsulation layer TFEL, the light shielding layer BM, the color filter layer CFL and the overcoat layer OC is the same as that described above and thus a detailed description thereof will be omitted.

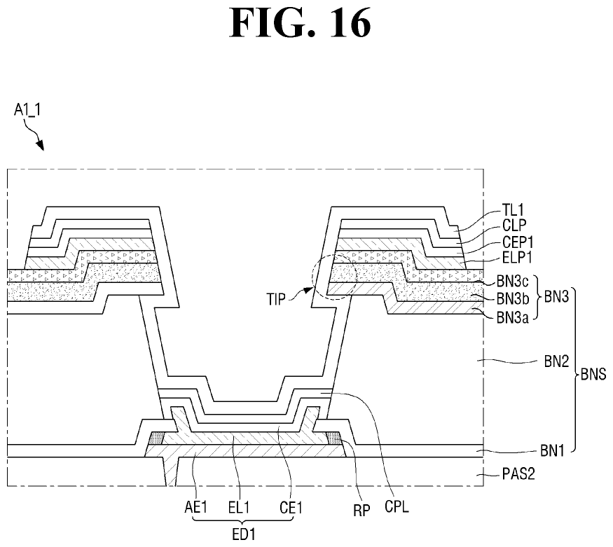

FIGS. 16 to 18 are cross-sectional views illustrating a part of a display device according to each of another embodiment.

Referring to FIGS. 16 to 18, in an embodiment, the third bank layer BN3 may have a multilayer structure of two or more layers. The multilayer structure of the third bank layer BN3 may be formed through a sputtering process.

The third bank layer BN3 may include a first metal nitride layer including or consisting of a metal nitride and a first metal layer including or consisting of a Group 5 metal element. As described above, the metal nitride of the first metal nitride layer may be titanium nitride (TiN).

The first metal layer of the third bank layer BN3 may include a Group 5 metal element. The Group 5 metal element may be vanadium (V), niobium (Nb), tantalum (Ta), or dubnium (Db). The Group 5 metal element may have excellent ductility, preventing the tip TIP of the third bank layer BN3 from breaking. The Group 5 metal element may be etched together with aluminum or/and titanium of the second bank layer by dry etching. In addition, the Group 5 metal element has relatively high resistance to a fluorine-based etchant, so that an undercut structure in which the sidewall of the second bank layer is depressed may be formed.

In an embodiment, the first metal layer may be thicker than the first metal nitride layer. The thickness of the first metal nitride layer may be thin because the deposition rate of the first metal nitride layer is lower than that of the first metal layer. In an embodiment, the thickness of the first metal nitride layer may be in the range of about 50 Å to about 300 Å, and the thickness of the first metal layer may be in the range of about 100 Å to about 1000 Å. When the thicknesses of the first metal nitride layer and the first metal layer are in the above range, respectively, the third bank layer may have both relatively high elasticity of the metal nitride and relatively high ductility of the Group 5 metal element without increasing the overall thickness of the third bank layer.

Referring to FIG. 16, in an embodiment, the third bank layer BN3 may have a triple layer structure BN3a, BN3b and BN3c. The first metal nitride layer BN3a including a metal nitride may be disposed on the second bank layer BN2, the first metal layer BN3b including a Group 5 metal element may be disposed on the first metal nitride layer BN3a, and the second metal nitride layer BN3c may be disposed on the first metal layer BN3b. The second metal nitride layer BN3c may include a metal nitride, and may include the same metal nitride as the metal nitride of the first metal nitride layer BN3a. In an embodiment, the first metal nitride layer BN3a may contact the second bank layer BN2.

In an embodiment, the thickness of the first metal layer BN3b is greater than each of the thicknesses of the first metal nitride layer BN3a and the second metal nitride layer BN3c. In an embodiment, the first metal nitride layer BN3a and the second metal nitride layer BN3c may include titanium nitride (TiN) and have a thickness of about 100 Å, and the first metal layer BN3b may include vanadium (V) and may have a thickness of about 200 Å.

In the case of including the structure of the first metal nitride layer BN3a/first metal layer BN3b/second metal nitride layer BN3c, the tip TIP of the third bank layer BN3 may retain its shape and thickness despite physical force such as a relatively high voltage applied in the subsequent process.

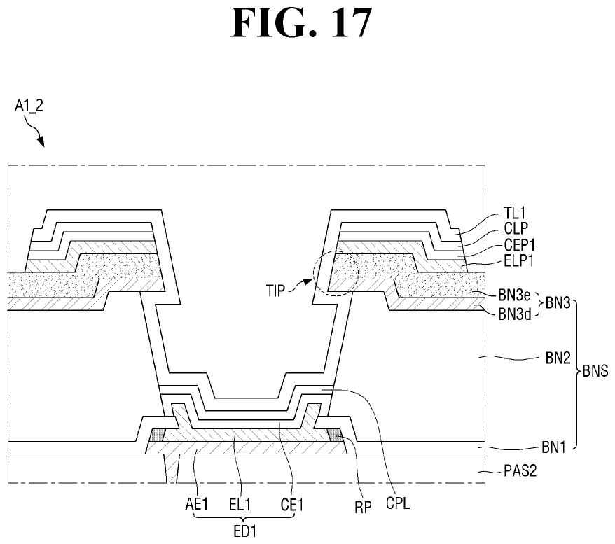

Referring to FIG. 17, in another embodiment, the third bank layer BN3 may have a double layer structure BN3d and BN3c. The first metal nitride layer BN3d including metal nitride may be disposed on the second bank layer BN2, and the first metal layer BN3e including a Group 5 metal element may be on the first metal nitride layer BN3d. In an embodiment, the thickness of the first metal layer BN3e may be greater than the thickness of the first metal nitride layer BN3d.

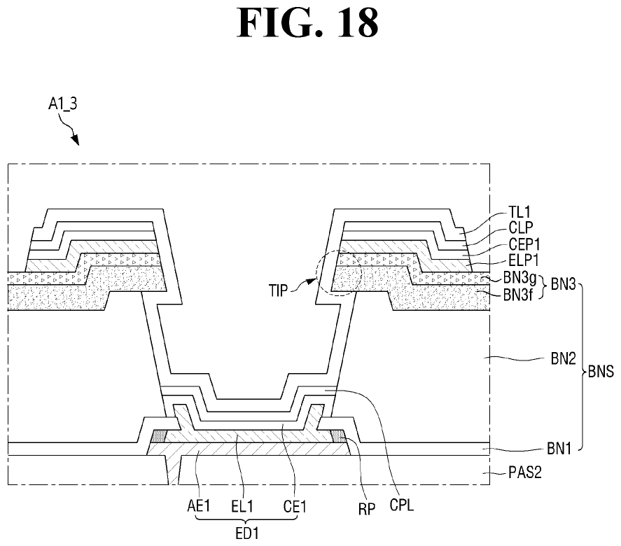

Referring to FIG. 18, in another embodiment, the third bank layer BN3 may have a double layer structure BN3f and BN3g. The first metal layer BN3f including a Group 5 metal element may be disposed on the second bank layer BN2, and the first metal nitride layer BN3g including a metal nitride may be disposed on the first metal layer BN3f. In an embodiment, the thickness of the first metal layer BN3f is greater than the thickness of the first metal nitride layer BN3g.

In an embodiment of FIGS. 16 to 18, the third bank layer BN3 is illustrated to have a double layer or triple layer structure, but the disclosure is not limited thereto. The third bank layer BN3 may have a stacked structure of quadruple layers or multi-layers including a larger number of metal nitride layers and metal layers.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a first pixel electrode and a second pixel electrode spaced apart from each other on a substrate;
a first bank layer disposed on the substrate and exposing the first pixel electrode and the second pixel electrode;
a first light-emitting layer disposed on the first pixel electrode and a second light-emitting layer disposed on the second pixel electrode;
a first common electrode disposed on the first light-emitting layer and a second common electrode disposed on the second light-emitting layer;
a second bank layer disposed on the first bank layer and exposing the first common electrode and the second common electrode; and
a third bank layer disposed on the second bank layer and including metal nitride, the third bank layer including:
a tip protruding further than a sidewall of the second bank layer.

2. The display device of claim 1,
wherein the first bank layer includes insulating material, and
the second bank layer includes metal material.

3. The display device of claim 1,
wherein a thickness of the third bank layer is in a range of about 100 angstroms to about 1500 angstroms.

4. The display device of claim 1,
wherein the third bank layer includes a first metal nitride layer including the metal nitride and a first metal layer including a Group 5 metal element.

5. The display device of claim 4,
wherein the first metal nitride layer contacts the second bank layer,
the first metal layer is disposed on the first metal nitride layer, and
the third bank layer further includes a second metal nitride layer disposed on the first metal layer and includes the metal nitride.

6. The display device of claim 4,
wherein a thickness of the first metal nitride layer is in a range of about 50 angstroms to about 300 angstroms, and
a thickness of the first metal layer is in a range of about 100 angstroms to about 1000 angstroms.

7. The display device of claim 1,
wherein the metal nitride is titanium nitride (TiN).

8. The display device of claim 1,
wherein the second bank layer includes one or more aluminum (Al) and titanium (Ti).

9. The display device of claim 1,
wherein a width of the tip of the third bank layer is in a range of about 0.1 micrometer to about 1.0 micrometer.

10. The display device of claim 1,
wherein the tip of the third bank layer overlaps the first common electrode in a thickness direction of the substrate.

11. The display device of claim 1,
wherein each of the first common electrode and the second common electrode are in direct contact with the sidewall of the second bank layer.

12. The display device of claim 1,
wherein a maximum distance from the substrate to the first common electrode is smaller than a maximum distance from the substrate to the second bank layer.

13. The display device of claim 1, further comprising:
a first organic pattern disposed on the third bank layer and including a same material as a material of the first light-emitting layer;
a first electrode pattern disposed on the first organic pattern and including a same material as a material of the first common electrode;
a second organic pattern disposed on the third bank layer and including a same material as a material of the second light-emitting layer; and
a second electrode pattern disposed on the second organic pattern and including a same material as a material of the second common electrode.

14. The display device of claim 13, further including:
a first inorganic layer disposed on the sidewall of the second bank layer adjacent to the first common electrode and disposed on the first common electrode and the first electrode pattern; and
a second inorganic layer disposed on the sidewall of the second bank layer adjacent to the second common electrode and disposed on the second common electrode and the second electrode pattern,
wherein the first inorganic layer and the second inorganic layer are spaced apart, and
a portion of the third bank layer is exposed in a space between the first inorganic layer and the second inorganic layer.

15. The display device of claim 1, further comprising:
a third pixel electrode disposed to be spaced apart from the second pixel electrode on the substrate;
a third light-emitting layer disposed on the third pixel electrode; and
a third common electrode disposed on the third light-emitting layer and disposed to be spaced apart from the second common electrode,
wherein the first bank layer exposes the third pixel electrode.

16. The display device of claim 15, further comprising:
a third organic pattern disposed on the third bank layer and including a same material as a material of the third light-emitting layer;
a third electrode pattern disposed on the third organic pattern and including a same material as a material of the third common electrode; and
a third inorganic layer disposed on the sidewall of the second bank layer adjacent to the third common electrode and disposed on the third common electrode and the third electrode pattern.

17. A method for fabricating a display device, the method comprising:
forming a plurality of pixel electrodes spaced apart from each other on a substrate, forming a first bank material layer on the substrate and the plurality of pixel electrodes, forming a second bank material layer on the first bank material layer; and forming a third bank material layer including a metal nitride on the second bank material layer;
defining a first hole overlapping a first pixel electrode among the plurality of pixel electrodes and penetrating the first bank material layer, the second bank material layer and the third bank material layer to expose the first pixel electrode;
wet etching a sidewall of the second bank material layer exposed through the first hole to form a tip of the third bank material layer protruding further than the sidewall of the second bank material layer;
forming a first light-emitting layer and a first common electrode on the first pixel electrode, and forming a first inorganic material layer on the first common electrode and the third bank material layer; and
removing a portion of the first inorganic material layer disposed on the third bank material layer.

18. The method of claim 17,
wherein the metal nitride is titanium nitride (TiN), and
wherein the second bank material layer includes one or more aluminum (Al) and titanium (Ti).

19. The method of claim 17,
wherein the first inorganic material layer includes any one of silicon oxide, silicon nitride, and silicon oxynitride, and
in removing the portion of the first inorganic material layer, a mask pattern is formed on the first inorganic material layer disposed in the first hole, and fluorine (F)-based etchant is used to etch the first inorganic material layer not covered by the mask pattern in a dry etching process.

20. The method of claim 19,
wherein, in the forming the first light-emitting layer and the first common electrode on the first pixel electrode and the forming the first inorganic material layer on the first common electrode and the third bank material layer,
a first organic pattern material layer disposed on the third bank material layer and including a same material as a material of the first light-emitting layer is formed and a first electrode pattern material layer disposed on the first organic pattern material layer and including a same material as a material of the first common electrode is formed, and
in the removing the portion of the first inorganic material layer, the first electrode pattern material layer and the first organic pattern material layer not covered by the mask pattern are etched simultaneously with the first inorganic material layer through a dry etching using the fluorine (F)-based etchant.
